(19) United States
(12) Patent Application Publication
(10) Pub. No.: US 2025/0133757 A1
(43) Pub. Date: Apr. 24, 2025

(54) SEMICONDUCTOR DEVICE AND METHOD FOR PRODUCING SEMICONDUCTOR DEVICE

(71) Applicant: FLOSFIA INC., Kyoto (JP)

(72) Inventors: Yusuke MATSUBARA, Kyoto (JP); Mitsuru OKIGAWA, Kyoto (JP); Hiroyuki ANDO, Kyoto (JP); Takashi SHINOHE, Kyoto (JP)

(21) Appl. No.: 19/005,007

(22) Filed: Dec. 30, 2024

Related U.S. Application Data
(63) Continuation-in-part of application No. PCT/JP2023/024229, filed on Jun. 29, 2023.

(30) Foreign Application Priority Data
Jun. 29, 2022 (JP) 2022-105187

(51) Int. Cl. H10D 8/60; H10D 8/01; H10D 62/00; H10D 62/53; H10D 62/80

(52) U.S. Cl. CPC H10D 8/60; H10D 8/051; H10D 62/01; H10D 62/53; H10D 62/875

(57) ABSTRACT

Provided a semiconductor device including: a semiconductor layer with an extended depletion layer; and an electrode disposed on the semiconductor layer directly or via another layer, the semiconductor layer including a first region containing, as a major component, a crystalline oxide semiconductor containing gallium, and a second region containing, as a major component, an oxide containing gallium, the second region including a linear crystal defect region in a cross section perpendicular to an upper surface of the semiconductor layer.

### CROSS REFERENCE TO RELATED APPLICATION

This application is a continuation-in-part application of International Patent Application No. PCT/JP2023/024229 (Filed on Jun. 29, 2023), which claims the benefit of priority from Japanese Patent Application No. 2022-105187 (filed on Jun. 29, 2022).

The entire contents of the above applications, which the present application is based on, are incorporated herein by reference.

### 1. FIELD OF THE INVENTION

The disclosure relates to a semiconductor device and a method of manufacturing a semiconductor device.

### 2. DESCRIPTION OF THE RELATED ART

A Schottky barrier diode having a p-type high resistance region has been disclosed. The p-type high resistance region is composed of a β-Ga₂O₃ single crystal formed by implanting Mg or Be ions and then annealing. Note that, technologies described in the background art are not necessarily recognized as conventional technologies.

### SUMMARY OF THE INVENTION

According to an example of the present disclosure, there is provided a semiconductor device including: a semiconductor layer with an extended depletion layer; and an electrode disposed on the semiconductor layer directly or via another layer, the semiconductor layer including a first region containing, as a major component, a crystalline oxide semiconductor containing gallium, and a second region containing, as a major component, an oxide containing gallium, the second region including a linear crystal defect region in a cross section perpendicular to an upper surface of the semiconductor layer.

According to an example of the present disclosure, there is provided a method of manufacturing a semiconductor device, the method including: forming a semiconductor layer containing, as a major component, a crystalline oxide semiconductor containing gallium, and an n-type dopant; ion implanting an impurity element into a portion of the semiconductor layer from an upper surface of the semiconductor layer; and forming an electrode on the semiconductor layer directly or via another layer without performing processing of activating the ion-implanted element, ion implanting including forming a first region containing, as a major component, a crystalline oxide semiconductor containing gallium, and a second region containing, as a major component, an oxide containing gallium, and forming a linear crystal defect region in the second region in a cross section perpendicular to the upper surface of the semiconductor layer.

Thus, according to the disclosure, a semiconductor region or semiconductor layer containing a crystalline oxide semiconductor containing gallium is used, and it is possible to provide a semiconductor device and a method of manufacturing the semiconductor device that enables to enhance breakdown voltage, even without providing a p-type semiconductor region or semiconductor layer.

### BRIEF DESCRIPTION OF THE DRAWINGS

FIG. 1 is a schematic cross-sectional view illustrating a semiconductor device according to a first embodiment.

FIG. 2 is a flowchart showing a method of manufacturing the semiconductor device according to the first embodiment.

FIG. 3 is a schematic cross-sectional view illustrating a semiconductor device according to a second embodiment.

FIG. 4 is a schematic cross-sectional view illustrating a semiconductor device according to a third embodiment.

FIG. 5 is a schematic cross-sectional view illustrating a semiconductor device according to a fourth embodiment.

FIG. 6 is a schematic cross-sectional view illustrating a semiconductor device according to a fifth embodiment.

FIG. 7 is a block diagram illustrating an example of a control system applying the semiconductor device according to an embodiment of the disclosure.

FIG. 8 is a circuit diagram illustrating an example of the control system applying the semiconductor device according to an embodiment of the disclosure.

FIG. 9 is a block configuration diagram illustrating another example of the control system applying the semiconductor device according to an embodiment of the disclosure.

FIG. 10 is a circuit diagram illustrating another example of the control system applying the semiconductor device according to an embodiment of the disclosure.

FIG. 11 is a view showing the relationship between voltage (V) and current (A) when a reverse voltage is applied to the semiconductor device in Example 1.

FIG. 12 is view showing results obtained by SEM observation of the semiconductor device in Example 1.

FIG. 13 is view showing results obtained by SEM observation of the semiconductor device in Example 1.

FIG. 14 is view showing results obtained by observing the semiconductor device in Example 1 with a scanning ion microscope (SIM).

FIG. 15 is view showing results obtained by SIM observation of the semiconductor device in Example 1.

FIG. 16 shows results of calculation using numerical calculation codes (SRIM/TRIM) indicating the relationship between depth from the upper surface of the semiconductor layer and density of crystal defects or concentration of impurity elements in Example 1.

FIG. 17 shows results of secondary ion mass spectrometry (SIMS) indicating the relationship between depth from the upper surface of the semiconductor layer and concentration of impurities in Examples 2 to 5.

### DETAILED DESCRIPTION

Embodiments of a semiconductor device according to the disclosure will be described below with reference to the drawings. However, the disclosure as defined by the claims is not limited to these embodiments. It should not be interpreted that all of combinations of configurations described in the embodiments are essential for solving the problem. Each configuration of the disclosure is described to the extent that it does not hinder the solution of the problem of the disclosure. Corresponding components are denoted by the same reference signs and duplicate description will be omitted.

As will be apparent to those skilled in the art, features shown in the drawings are not necessarily depicted at a fixed scale, even if not stated herein. It should also be noted that one feature in one form may be used in another form. Descriptions of well-known elements and processing techniques may be omitted so as not to render the embodiments of the disclosure needlessly ambiguous. The examples used herein are merely intended to aid in understanding the disclosure and to enable those skilled in the art to further implement the embodiments of the disclosure. Accordingly, the embodiments and examples herein are not to be construed as limited to the scope of the disclosure, which is defined solely by the claims and applicable laws.

Terms such as “first” and “second” may be used to describe the various elements used herein, but the elements are not to be limited by these terms. Terms such as “first” and “second” are used only to distinguish one element from another. For example, without departing from the scope of the disclosure, a first element may be referred to as a second element, and a second element may be referred to as a first element. As used herein, the term “and/or” encompasses some or all combinations of one or more of the listed items.

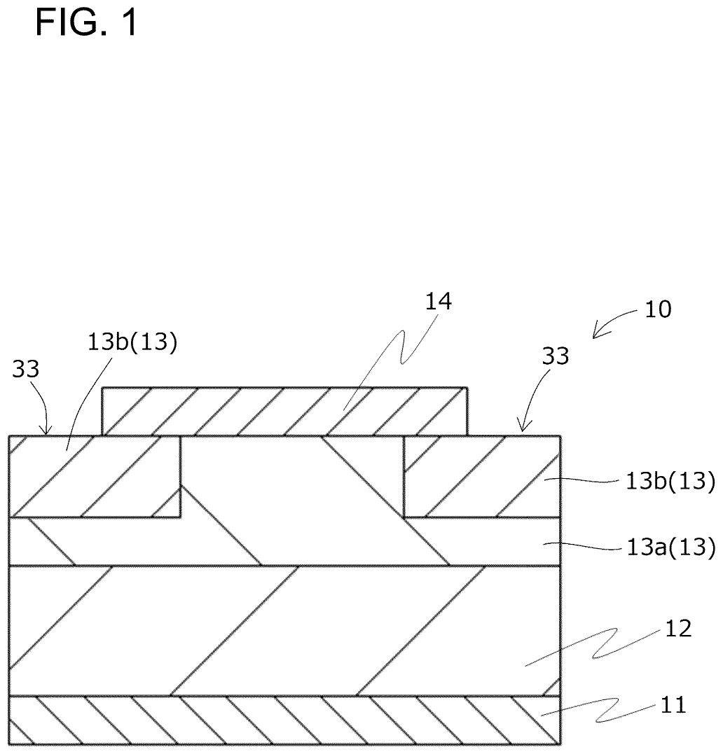

In the disclosure, one side in a direction parallel to the depth direction of the semiconductor layer is defined as “up,” and the other side is defined as “down.” In particular, “up” and “down” are defined as the Schottky electrode 14 side is upper side as viewed from the n-type semiconductor layer 13 of the semiconductor device 10 in FIG. 1, and the ohmic electrode 11 side is lower side as viewed from the n+ type semiconductor layer 12. Of the two principal surfaces of the layer, substrate or other material, the surface located above is described as the upper surface and the surface located below as the lower surface. These “up” and “down” directions are not limited to the direction of gravity or the direction of attachment of the semiconductor device to the substrate or the like during mounting. In this disclosure, the direction orthogonal to the depth direction of the semiconductor layer is described as the horizontal direction. Although the description herein uses the phrase “top view,” it may be paraphrased as “flat view.”

When an expression such as an element, e.g., a layer, area, or substrate is present “on” or “under” another element is used, it is to be understood that the element or the like may be directly on or under another element, or yet another element may be interposed therebetween. When expressions such as an element is “connected” or “joined” to another element are used, it is to be understood that the element may be directly connected or joined to another element, or yet another element may be interposed therebetween.

The terms used herein are intended to describe only certain forms of the disclosure and are not intended to limit the disclosure. The terms “provided with” and “including” as used herein indicate the presence of the described elements and do not exclude the presence of one or more other elements.

Unless otherwise defined, all terms used herein (including technical and scientific terms) have the same meaning as generally understood by those skilled in the art to which the disclosure pertains. Terms used herein are to be interpreted as having a meaning consistent with their meaning in the context of this specification and in the related art. It is also to be understood that, unless otherwise stated, terms used herein are not to be interpreted in an idealized or overly formalistic sense.

The semiconductor device according to the disclosure is useful as various semiconductor elements, especially for power devices. Semiconductor devices may be classified into horizontal elements (horizontal devices), in which electrodes are formed on one side of the semiconductor layer and current flows in the film thickness direction of the semiconductor layer and in the in-plane direction of the film plane, and vertical elements (vertical devices), in which electrodes are provided on the front and back sides of the semiconductor layer and current flows in the film thickness direction of the semiconductor layer. Embodiments of the semiconductor element according to the disclosure may be suitably used for both a horizontal device and a vertical device, but vertical devices are especially preferred. Examples of the semiconductor device include a Schottky barrier diode (SBD), a junction barrier Schottky diode (JBS), a metal semiconductor field effect transistor (MESFET), a metal insulator semiconductor field effect transistor (MISFET), a metal oxide semiconductor field effect transistor (MOSFET), a high electron mobility transistor (HEMT), a light-emitting diode, and the like. In the embodiments of the disclosure, the semiconductor device is preferably a diode, more preferably a Schottky barrier diode (SBD). Additionally, in the embodiments of the disclosure, the semiconductor device is also preferably a MOSFET.

### First Embodiment

FIG. 1 is a schematic cross-sectional view illustrating a semiconductor device 10 according to a first embodiment. The semiconductor device 10 according to the first embodiment is, for example, a Schottky barrier diode (SBD). As shown in FIG. 1, the semiconductor device 10 includes an ohmic electrode 11, an n+ type semiconductor layer 12, an n− type semiconductor layer 13, and a Schottky electrode 14. Although not shown, the semiconductor device 10 may also include a support substrate of a conductor made of a known material and disposed under the ohmic electrode 11.

The ohmic electrode 11 is an electrode that makes ohmic contact with the n+ type semiconductor layer 12. The material of the ohmic electrode 11 may be the same as the material of the Schottky electrode 14 (described in detail below) or may be a known material.

The n+ type semiconductor layer 12 is located on the ohmic electrode 11. The n+ type semiconductor layer 12 is an n-type semiconductor layer having a greater carrier density than that of the n− type semiconductor layer 13. The n+ type semiconductor layer 12 contains a crystalline oxide semiconductor as its major component.

An example of the crystalline oxide semiconductor included in the n+ type semiconductor layer 12 is a metal oxide containing one or more metals selected from aluminum, gallium, indium, iron, chromium, vanadium, titanium, rhodium, nickel, cobalt, and iridium.

In the embodiments of the disclosure, the crystalline oxide semiconductor preferably contains at least one metal selected from aluminum, indium and gallium, more preferably contains at least gallium, and is most preferably α-Ga₂O₃ or a mixed crystal thereof. According to the disclosure, it is possible to reduce leakage current well even when a semiconductor having a large band gap, such as gallium oxide or a mixed crystal thereof, is used.

The crystalline structure of the crystalline oxide semiconductor included in the n+ type semiconductor layer 12 is, for example, a corundum structure, a β-gallia structure, a hexagonal structure (e.g., an ε-type structure), an orthorhombic structure (e.g., a x-type structure), a cubic structure, a tetragonal structure, or the like. In the embodiments of the disclosure, the crystalline oxide semiconductor preferably has a corundum structure, a β-gallia structure, or a hexagonal structure (e.g., an ε-type structure), more preferably has a corundum structure. The term “major component” means that the n+ type semiconductor layer 12 preferably the crystalline oxide semiconductor in an atomic ratio of 50% or more, more preferably 70% or more, even more preferably 90% or more relative to the total components of the n+ type semiconductor layer 12. Note that the content may be 100%.

The thickness of the n+ type semiconductor layer 12 may be 1 μm or less, or 1 μm or more. In the embodiments of the disclosure, the thickness of the n+ type semiconductor layer 12 is preferably 1 m or more, and preferably 3 μm or less. Note that the thickness of the n+ type semiconductor layer 12 may be 3 μm or more.

The area of the n+ type semiconductor layer 12 in a top view may be 1 mm² or more or 1 mm² or less. The area is preferably 2 mm² to 300 cm². In this embodiment, the n+ type semiconductor layer 12 is a monocrystalline, but the n+ type semiconductor layer 12 may be polycrystalline.

The carrier density of the n+ type semiconductor layer 12 may be set accordingly by adjusting the doping amount. The n+ type semiconductor layer 12 preferably contains a dopant. The dopant may be any known dopant. In the embodiments of the disclosure, when the n+ type semiconductor layer 12 contains, as a major component, the crystalline oxide semiconductor containing gallium, suitable examples of the dopant include n-type dopants such as tin, germanium, silicon, titanium, zirconium, vanadium or niobium. In the embodiments of the disclosure, the n-type dopant is preferably Sn, Ge or Si. In the composition of the n+ type semiconductor layer 12, the content of the dopant is preferably 0.00001 atom % or more, more preferably 0.0001 atom % to 20 atom %, and most preferably 0.00001 atom % to 10 atom %. The carrier density of the n+ type semiconductor layer 12 is typically about 1×10¹⁷/cm³ to 1×10²²/cm³. In the embodiments of the disclosure, the dopant may be included at a high concentration of about 1×10²⁰/cm³ or more. In the embodiments of the disclosure, the dopant is preferably included at a concentration that achieves a carrier density of 1×10¹⁷/cm³ or more.

The n− type semiconductor layer 13 is located on the n+ type semiconductor layer 12. The n− type semiconductor layer 13 is in Schottky contact with the Schottky electrode 14 at an upper surface of the n− type semiconductor layer 13. The n− type semiconductor layer 13 is an n-type semiconductor layer having a carrier density smaller than that of the n+ type semiconductor layer 12. The n-type semiconductor layer 13 is a layer in which a depletion layer extends when a reverse voltage is applied to the semiconductor device 10. The carrier density of the n− type semiconductor layer 13 is typically in the range of 1.0×10¹⁴/cm³ to 1.0×10¹⁷/cm³.

The thickness of the n− type semiconductor layer 13 may be 1 μm or less or 1 μm or more. In the embodiments of the disclosure, the thickness of the n− type semiconductor layer 13 is preferably 3 m or more. The area of the n− type semiconductor layer 13 in a flat view is not particularly limited and may be 1 mm² or more or 1 mm² or less but is preferably 2 mm² to 300 cm².

The n− type semiconductor layer 13 includes a first region 13a and a second region 13b. The n− type semiconductor layer 13 may include other regions. The second region 13b is an example of a second region or an impurity-doped region.

An upper surface of the first region 13a is Schottky-coupled to the Schottky electrode 14. The first region 13a is, for example, a region of the n− type semiconductor layer 13 excluding the second region 13b. As shown in FIG. 1, the first region 13a comprises a lower surface of the n− type semiconductor layer 13, a portion of the upper surface of the n− type semiconductor layer 13, and a portion of a side surface of the n− type semiconductor layer 13.

The first region 13a is a semiconductor region containing a crystalline oxide semiconductor as a major component. The crystalline oxide semiconductor preferably contains at least gallium and is most preferably α-Ga₂O₃ or a mixed crystal thereof. In the embodiments of the disclosure, the crystalline oxide semiconductor serving as the major component of the n+ type semiconductor layer 12 and the crystalline oxide semiconductor serving as the major component of the first region 13a may be the same or different.

Examples of the crystalline structure of the crystalline oxide semiconductor contained in the first region 13a include a corundum structure, a β-gallia structure, a hexagonal structure (e.g., an F-type structure), an orthorhombic structure (e.g., a x-type structure), a cubic structure, a tetragonal structure, and the like. In the embodiments of the disclosure, the crystalline oxide semiconductor preferably has a corundum structure, a β-gallia structure, or a hexagonal structure (e.g., an F-type structure), more preferably has a corundum structure. Note that, the term “major component” means, for example, that when the crystalline oxide semiconductor is Ga₂O₃, Ga₂O₃ is included in the first region 13a in a ratio where the atomic ratio of gallium in all metallic elements in the first region 13a is 0.5 or more. In this disclosure, the atomic ratio of gallium in all metallic elements in the first region 13a is preferably 0.7 or more, more preferably 0.9 or more. In this embodiment, the first region 13a is monocrystalline but may also be polycrystalline.

The first region 13a has a carrier density smaller than that of the n+ type semiconductor layer 12. The carrier density of the first region 13a may be set accordingly by adjusting the doping amount of the n− type semiconductor layer 13. The first region 13a may contain a dopant. The dopant may be a known dopant. In the embodiments of the disclosure, particularly when the first region 13a contains, as a major component, a gallium-containing crystalline oxide semiconductor, suitable examples of the dopant include n-type dopants such as tin, germanium, silicon, titanium, zirconium, vanadium, and niobium. In the embodiments of the disclosure, the n-type dopant is preferably Sn, Ge, or Si. In the composition of the first region 13a, the content of the dopant is preferably 0.00001 atom % or more, more preferably 0.0001 atom % to 20 atom %, most preferably 0.00001 atom % to 10 atom %. More specifically, the concentration of the dopant may typically be about 1×10¹⁶/cm³ to 1×10²²/cm³, or the concentration of dopant may be as low as about 1×10¹⁷/cm³ or less, for example. Note that, herein, dopant refers to an element to be converted into a donor or an acceptor.

The second region 13b is, for example, a region extending from a portion of the upper surface of the n− type semiconductor layer 13 downward to a depth of 1.0 μm or more in the n− type semiconductor layer 13. The depth may be 1.0 μm but is preferably 1.2 μm or more or 1.5 μm or more. A portion of the second region 13b overlaps a peripheral edge 33 of the n− type semiconductor layer 13 in a top view. The peripheral edge 33 is a region within a certain range inward from the side surface of the n− type semiconductor layer 13. The certain range is, for example, a range that does not overlap a lower surface of the Schottky electrode 14 in a top view. The upper surface of the second region 13b is an example of an upper edge of the second region 13b. In this embodiment, since the upper surface of the second region 13b is included in the upper surface of the n− type semiconductor layer 13, the depth in the n-type semiconductor layer 13 in which the second region 13b is located also corresponds to the thickness of the second region 13b.

A portion of the upper surface of the second region 13b is in contact with a portion of the lower surface of the Schottky electrode 14. A portion of the second region 13b overlaps, for example, in a top view, a portion of the lower surface of the Schottky electrode 14 within a certain range inward of the periphery of the lower surface. In this embodiment, the second region 13b and the first region 13a are continuous, but another region may be provided between these regions. When the first region 13a and the second region 13b are continuous, there may be no clear boundary between them.

The second region 13b is preferably continuous in a top view. The second region 13b may, for example, be ring-shaped, rectangular frame-shaped, or bar-shaped in a top view. Note that, the second region 13b may not be continuous in a top view and may be composed of a plurality of non-contiguous regions. In this case, in a top view, the second region 13b may be stripe-shaped, or each portion of the second region 13b may be L-shaped or dot-shaped.

The second region 13b is a region containing an oxide as a major component. The oxide is more preferably an oxide containing at least gallium, most preferably Ga₂O₃, a composite oxide of Ga₂O₃ and another metal oxide, or a mixture of Ga₂O₃ and another metal oxide. Although the oxide may be a crystalline oxide semiconductor, it is preferable that the oxide is a fine crystal, and it is more preferable that the oxide is non-crystalline. It is preferable that the oxide includes amorphous or is amorphous. Note that, the second region 13b may be a mixture of the crystalline semiconductor and the non-crystalline.

When the oxide serving as a major component in the second region 13b includes a crystalline oxide semiconductor, the crystalline structure of the crystalline oxide may be, for example, a corundum structure, a β-gallia structure, a hexagonal structure (e.g., an ε-type structure), an orthorhombic structure (e.g., a x-type structure), a cubic structure, or a tetragonal structure. In the embodiments of the disclosure, the crystalline oxide semiconductor preferably has a corundum structure, a β-gallia structure, or a hexagonal structure (e.g., an ε-type structure), more preferably a corundum structure. The crystalline oxide semiconductor is equivalent to the crystal structure of the crystalline oxide semiconductor in the first region 13a. Note that, the term “major component” means, for example, that when the oxide is Ga₂O₃, Ga₂O₃ is included in the second region 13b in a ratio where the atomic ratio of gallium in all metallic elements in the second region 13b is 0.5 or more. Herein, the atomic ratio of gallium in all metallic elements in the second region 13b is preferably 0.7 or more, more preferably 0.9 or more.

The major component of the n− type semiconductor layer 13 may be a crystalline oxide semiconductor. The crystalline oxide semiconductor included in the n− type semiconductor layer 13 may be only the crystalline oxide semiconductor included in the first region 13a or may be combination of the crystalline oxide semiconductor included in the first region 13a and the crystalline oxide semiconductor included in the second region 13b. The term “major component” means that, of the total components of the n-type semiconductor layer 13, in terms of atomic ratio, the crystalline oxide semiconductor accounts for preferably 50% or more, more preferably 70% or more, more preferably 90% or more, and may accounts for even 100%.

The second region 13b has a carrier density smaller than that of the first region 13a. The second region 13b may contain the same dopant as the first region 13a. The dopant may be a known dopant. In the embodiments of the disclosure, examples of the dopant include n-type dopants such as tin, germanium, silicon, titanium, zirconium, vanadium, and niobium. In the embodiments of the disclosure, in the composition of the second region 13b, the content of the dopant may be 0.00001 atom % or more, or may be 0.00001 atom % to 20 atom % or 0.00001 atom % to 10 atom %. More specifically, the concentration of the dopant may be about 1×10¹⁶/cm³ to 1×10²²/cm³ or as low as, for example, 1×10¹⁷/cm³ or less.

In addition to the dopant, the second region 13b further contains, for example, ion implanted impurities. The impurities are elements different from the elements constituting the major component of the second region 13b, and the concentration of the impurities is typically 1.0×10¹⁵/cm³ to 1.0×10²²/cm³. Note that, herein, “impurity” may be written as “impurity element.” The elements in the second region 13b excluding the impurity element may be the same as the elements in the first region 13a.

Herein, the impurity element may be a compound. For example, the impurity element is included in the second region 13b by itself. Although multiple impurity elements may be selected for ion implantation, in this embodiment, one impurity element is selected. The impurity element is preferably selected from an element that does not function as a donor or acceptor for gallium oxide. The impurity is preferably an element for which the amount of damage to a crystalline oxide semiconductor containing gallium is relatively easily adjusted when ion implanted. Factors that may cause the damage amount to vary include the mass number of the impurity element and the value of the implantation energy. If the mass number of the impurity element is too small, little damage is done to the area in the gallium oxide-based crystal through which the ion-implanted impurity passes, and the area that can be damaged will be too far from the lower surface of the Schottky electrode 14 to improve the breakdown voltage of the semiconductor device. This means that it is not possible to improve the breakdown voltage of the semiconductor device. If the mass number of the impurity element is too large, too many crystal defects will be generated as the amount of damage increases, which may degrade the breakdown voltage of the semiconductor device. In addition, a greater amount of implantation energy is required as the mass number of the impurity element increases, and thus more restriction is placed on the load and configuration of the ion implantation equipment, which is industrially disadvantageous.

Preferred impurity elements are metallic elements with a mass number greater than Mg, more preferably aluminum (Al). The ions may be implanted by box profile implantation or single profile implantation. According to the disclosure, it is possible to improve the breakdown voltage of the semiconductor device even with single profile implantation.

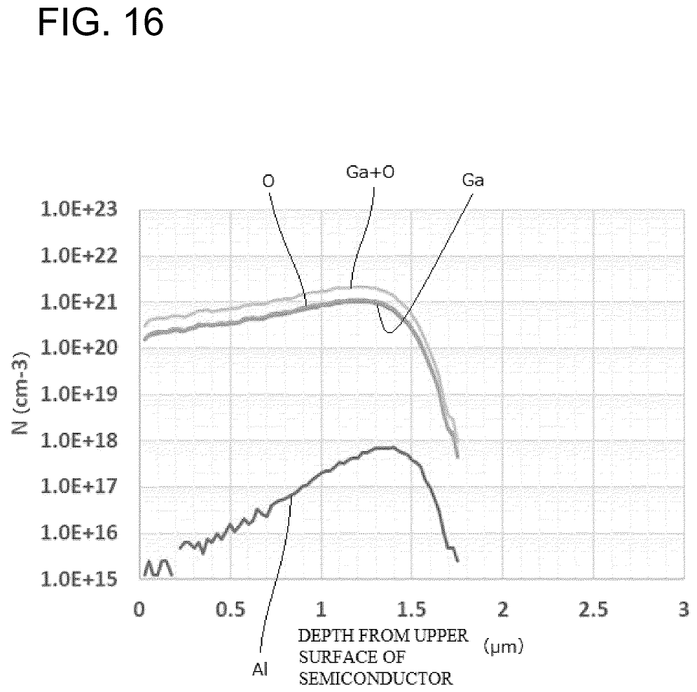

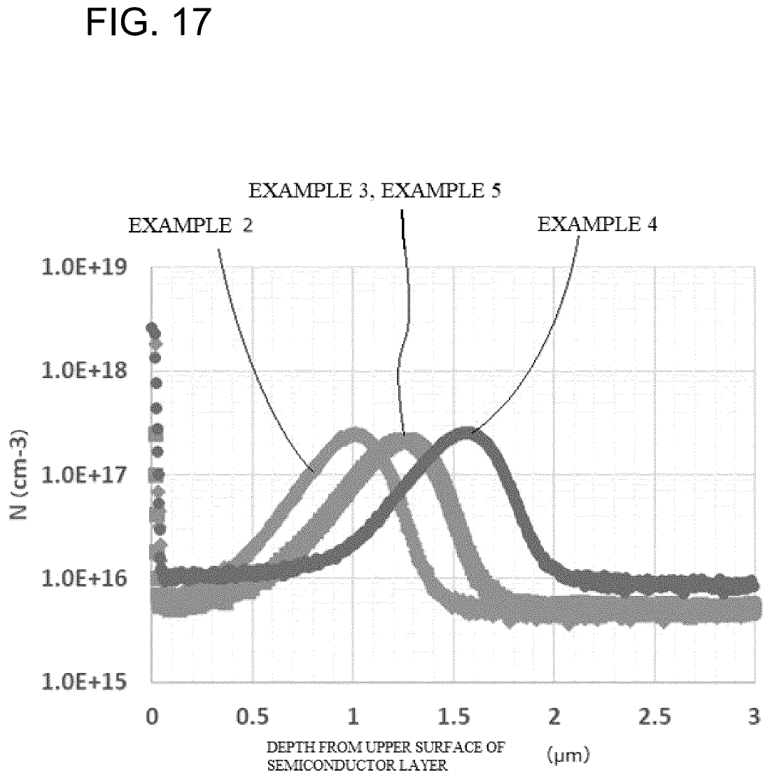

The maximum value of the concentration of the impurity element included in the second region 13b is at a depth of 1.0 μm or more from the upper surface of the n− type semiconductor layer 13 (see Examples 1-5 and FIGS. 16 and 17). The maximum value of the concentration of the impurity element is greater than the maximum value of the concentration of the impurities in the first region 13a. Herein, the concentration of the impurity elements is sometimes referred to as “impurity concentration.” The maximum value of the impurity concentration is measured, for example, using secondary ion mass spectrometry (SIMS). In this embodiment, for example, the depth is 2.0 μm or less. The maximum value of the impurity concentration is 1.0×10¹⁷/cm³ or more. Note that, the maximum value may be a peak value. In the embodiments of the disclosure, the maximum value of the impurity concentration in the second region 13b is preferably greater than the concentration of the dopant. The peak of the ion-implanted impurities may be at a lower edge of the second region 13b.

As described above, the maximum value of the concentration of the impurity element in the second region 13b is identified by secondary ion mass spectrometry (SIMS), for example, but may also be identified or observed by known equipment, data, or analytical methods, such as transmission electron microscopy (TEM), energy dispersive X-ray spectroscopy (TEM-EDX), another secondary ion mass spectrometry method (NanoSIMS) or calculated using numerical codes (SRIM/TRIM).

Herein, the projected range of ion implantation depth into the n− type semiconductor layer 13 is Rp and the standard deviation ΔRp. Rp+ΔRp is, for example, greater than 1.1 μm.

The second region 13b may include crystal defects formed, for example, by ion implantation from the upper surface of the n− type semiconductor layer 13. The crystal defects may be observed, for example, by a cross-sectional TEM (transmission electron microscope) image or a cross-sectional SEM (scanning electron microscope) image. The crystal defects may be observed as a plurality of defects dispersed generally evenly in the second region 13b, or as a plurality of defects diffused in a plane or linear manner at the upper or lower edge of the second region 13b.

In this embodiment, for example, in an image showing a cross-section perpendicular to the upper surface of the semiconductor layer, a crystal defect region 21 containing a relatively high density of crystal defects is observed in a linear shape, and a region including the crystal defect region 21 is defined as the second region 13b. The crystal defect region 21 may be observed as a region with high resistance. It is sufficient if at least a part of the second region 13b is the crystal defect region 21. In this embodiment, for example, the lower edge of the second region 13b is deeper than the lower edge of the crystal defect region 21 in terms of depth from the upper surface of the n− type semiconductor layer 13. A portion of the second region 13b may not be observed in the image, for example, a portion extending from the lower end of the second region 13b upward may not be observed in the image.

The linear crystal defect region 21 according to this disclosure is observed as a two-dimensional region and has a certain area. In this embodiment, the linear crystal defect region 21 extends along the upper surface of the n− type semiconductor layer 13, that is, parallel to the upper surface of the n− type semiconductor layer 13. The crystal defect region 21 has a certain thickness. The thickness is, for example, 1.0 μm or more. The thickness may be 1.2 μm or more. Note that, the linear shape according to this embodiment may also be described as a rod, a band, or simply a long, thin shape. Further, the crystal defect region 21 is, for example, linear but at least a part of the crystal defect region 21 may be curved.

A portion of the crystal defect region 21 is, for example, located directly below a horizontal edge of the Schottky electrode 14 in an image showing a cross-section perpendicular to the upper surface of the n− type semiconductor layer 13. This portion of the crystal defect region 21 may be observed as sharing a boundary with the Schottky electrode 14.

The density of crystal defects in the crystal defect region 21 is, for example, 1.0×10¹⁹/cm³ or more. The density is preferably 1.0×10²⁰/cm³ or more. The density may be 1.0×10¹⁸/cm³ or more to a value less than 1.0×10²⁰/cm³ or more. In addition, the maximum value of the density is, for example, 1.0×10²¹/cm³ or more. The density of crystal defects in the first region 13a that does not include the crystal defect region 21 is, for example, less than 1.0×10¹⁸/cm³ and may be less than this value.

The surface density of crystal defects in the second region 13b in a top view of the n− type semiconductor layer 13 is, for example, 5×10¹⁶/cm² or more. The surface density is preferably 1×10¹⁷/cm² or more.

The Schottky electrode 14 is disposed on the n− type semiconductor layer 13. The Schottky electrode 14 may be capable of forming a Schottky junction with the n− type semiconductor layer 13. The constituent material of the Schottky electrode 14 may be a conductive inorganic material or a conductive organic material. In the embodiments of the disclosure, the constituent material of the Schottky electrode 14 is preferably a metal. Suitable examples of the metal include at least one metal selected from Group 4 to Group 10 of the periodic table. The metals in Group 4 of the periodic table include titanium (Ti), zirconium (Zr), and hafnium (Hf). Metals in Group 5 of the periodic table include vanadium (V), niobium (Nb), and tantalum (Ta). Metals in Group 6 of the periodic table include chromium (Cr), molybdenum (Mo), and tungsten (W). Metals in Group 7 of the periodic table include manganese (Mn), technetium (Tc), and rhenium (Re). Metals in Group 8 of the periodic table include iron (Fe), ruthenium (Ru), and osmium (Os). Metals in Group 9 of the periodic table include cobalt (Co), rhodium (Rh), and iridium (Ir). Metals in Group 10 of the periodic table include nickel (Ni), palladium (Pd), and platinum (Pt). The thickness of the Schottky electrode is not particularly limited and is preferably 0.1 nm to 10 μm, more preferably 5 nm to 500 nm, most preferably 10 nm to 200 nm. In the embodiments of the disclosure, the Schottky electrode 14 may include a first electrode layer provided on the n− type semiconductor layer 13 and a second electrode layer provided on the first electrode layer. Note that, in the embodiments of the disclosure, the thickness of the first electrode layer is preferably thinner than the thickness of the second electrode layer. Further, in the embodiments of the disclosure, the work function of the first electrode layer is preferably greater than the work function of the second electrode layer. When the first electrode layer has this preferred configuration, the resulting semiconductor device has more excellent Schottky characteristics and the effect of improving reverse breakdown voltage is better expressed. In the embodiments of the disclosure, the Schottky electrode 14 may be a single layer or may have two or more metal layers.

According to this configuration, it is possible to increase breakdown voltage without providing a p-type semiconductor region. In addition, with this configuration, it is possible to reduce the electric field concentration at the outer peripheral edge of the Schottky electrode 14.

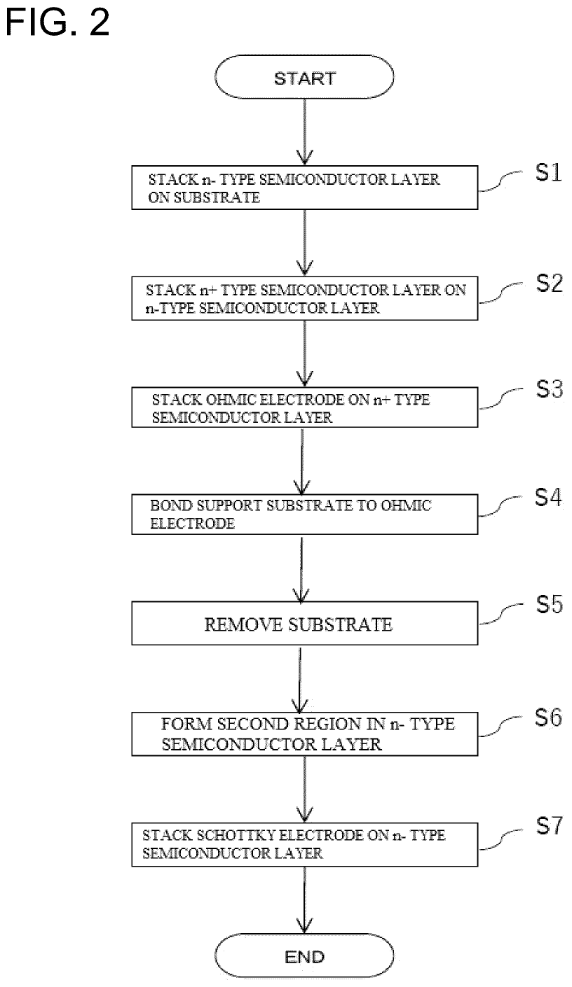

An example of a method of manufacturing a semiconductor device 10 will now be described with reference to FIGS. 1 and 2. FIG. 2 is a flowchart showing an example of a method of manufacturing a semiconductor device according to the disclosure.

As shown in FIG. 2, the method of manufacturing the semiconductor device 10 includes, for example, a step S1 in which the n− type semiconductor layer 13 is stacked on a substrate 15, a step S2 in which the n+ type semiconductor layer 12 is stacked on the n− type semiconductor layer 13, a step S3 in which the ohmic electrode 11 is stacked on the n+ type semiconductor layer 12, a step S4 in which a support substrate is bonded to the ohmic electrode 11, a step S5 in which the substrate 15 is removed from the n− type semiconductor layer 13, a step S6 in which the second region 13b is formed in the n− type semiconductor layer 13, and a step S7 in which the Schottky electrode 14 is stacked on the n-type semiconductor layer 13.

In step S1, the n− type semiconductor layer 13 is stacked on the substrate 15 by, for example, a mist CVD method. Note that, the n− type semiconductor layer 13 may be stacked on the substrate 15 by any known method. The n− type semiconductor layer 13 may be formed by a method other than a mist CVD method, such as a CVD method, a MOCVD method, a MOVPE method, a mist epitaxy method, an MBE method, an HVPE method, a pulse growth method, or an ALD method. In the embodiments of the disclosure, the n− type semiconductor layer 13 is preferably formed by a mist CVD method or a mist epitaxy method. In the mist CVD method or the mist epitaxy method, for example, a raw material solution is atomized (atomization step), the droplets are suspended and atomized, and the resulting atomized droplets are transported onto a substrate by a carrier gas (transportation step). Then, the atomized droplets are thermally reacted in the vicinity of the substrate such that a semiconductor film containing a crystalline oxide semiconductor as a major component is deposited on the substrate 15 (deposition process), thereby forming the n− type semiconductor layer 13.

The substrate 15 is, for example, a plate-shaped sapphire substrate. The substrate 15 may be any substrate capable of supporting a semiconductor film. The substrate 15 may be an insulator substrate, a semiconductor substrate, a metal substrate, or a conductive substrate, but the substrate 15 is preferably an insulator substrate or a substrate including a metal film on its surface. The examples of substrate 15 include a base substrate containing a substrate material having a corundum structure as a major component, a base substrate containing a substrate material having a β-gallia structure as a major component, or a base substrate containing a substrate material having a hexagonal crystal structure as a major component. Herein, “major component” means that the substrate contains the substrate material having the specific crystal structure described above in an atomic ratio of preferably 50% or more, more preferably 70% or more, even more preferably 90% or more relative to the total components of the substrate material, and the content of the substrate material may be 100%.

The substrate material may be any known substrate material. Suitable examples of the substrate material having a corundum structure described above include α-Al₂O₃ (sapphire substrate) and α-Ga₂O₃, and a-plane sapphire substrates, m-plane sapphire substrates, r-plane sapphire substrates, c-plane sapphire substrates, or α-type gallium oxide substrates (a-plane, m-plane, or r-plane) are more suitable. Examples of the base substrate containing a substrate material having a β-gallia structure as a major component include β-Ga₂O₃ substrates and mixed crystal substrates containing Ga₂O₃ and Al₂O₃, in which Al₂O₃ is greater than 0 wt % and 60 wt % or less. Examples of the base substrate containing a substrate material having a hexagonal crystal structure a major component include SiC substrates, ZnO substrates, and GaN substrates.

In step S2, the n+ type semiconductor layer 12 is stacked on the n− type semiconductor layer 13 by, for example, a mist CVD method. The n+ type semiconductor layer 12 may be stacked by the same method as used for the n− type semiconductor layer 13. Note that the n+ type semiconductor layer 12 may be stacked on the substrate 15 by the same known method as that used for the n− type semiconductor layer 13. In the embodiments of the disclosure, the method of forming the n+ type semiconductor layer 12 is preferably a mist CVD method or a mist epitaxy method. In the mist CVD method or the mist epitaxy method, for example, a raw material solution is atomized (atomization step), the droplets are suspended and atomized, and the resulting atomized droplets are transported onto a substrate by a carrier gas (transportation step). Then, the atomized droplets are thermally reacted in the vicinity of the substrate such that a semiconductor film containing a crystalline oxide semiconductor as a major component is deposited on the substrate 15 (deposition process), thereby forming the n+ type semiconductor layer 12.

In step S3, the ohmic electrode 11 is stacked on the n+ type semiconductor layer 12. The ohmic electrode 11 may be formed by any known method. Examples of the method of forming the ohmic electrode 11 include a dry method and a wet method. Examples of the dry method include sputtering, vacuum deposition, and CVD. Examples of the wet method include screen printing and die coating.

In step S4, the support substrate is bonded to the ohmic electrode 11. Note that the support substrate may be any known substrate. The support substrate is, for example, a metal support substrate. Note that, a known conductive adhesive layer is used to bond the support substrate and the ohmic electrode 11. The conductive adhesive layer is, for example, an Ag sintered layer.

In step S5, the substrate 15 is removed from the n− type semiconductor layer 13. At this time, a known method such as peeling is used to remove the n− type semiconductor layer 13 from the substrate 15.

In step S6, the second region 13b is formed in the n− type semiconductor layer 13. In step S6, an impurity element is ion-implanted into the n− type semiconductor layer 13 to a depth of 1.0 m or more from the upper surface of the n− type semiconductor layer 13. The element to be ion-implanted is, for example, Al. At this time, the implantation energy is, for example, 1500 to 3000 keV. The dose of Al is, for example, 1.0×10³ atoms/cm² to 4.0×10¹⁴ atoms/cm². The implantation beam current is, for example, 140 to 260 nA. The implantation time is, for example, 83.0 to 253.0 sec. The equipment used is, for example, a device with a maximum implantation energy of 8 MeV. The element to be ion-implanted does not have to be Al, and any element with a higher mass number than Mg may be used.

In this embodiment, in the n− type semiconductor layer 13, the ion-implanted region and the region through which the ion-implanted element has passed are the second region 13b. In the n− type semiconductor layer 13, a region excluding the ion-implanted region and the region through which the ion-implanted element has passed is the first region 13a. In step S6, the maximum value of the concentration of the impurity element in the second region 13b is made larger than the maximum value of the concentration of the impurity element in the first region 13a. In step S6, the linear crystal defect region 21 observed in a cross section perpendicular to the upper surface of the n− type semiconductor layer 13 is formed in the second region 13b.

For example, as shown in FIGS. 17, when high and low concentrations of the impurity element appear in the depth from the upper surface of the n− type semiconductor layer 13, it is understood that the n− type semiconductor layer 13 includes the second region 13b. In particular, in a case where the impurity profile has a maximum value (peak value), as shown in FIGS. 17 and 18, the depth at which the slope of the profile is substantially zero at a position deeper than the maximum value may be the boundary between the lower edge of the second region 13b and the upper edge of the first region 13a for convenience. On the other hand, in a case where the impurity profile does not have a maximum value, such as a box profile, the depth at which the slope of the profile is substantially zero at a position deeper than the maximum value may be the boundary between the lower edge of the second region 13b and the upper edge of the first region 13a for convenience.

In step S7, the Schottky electrode 14 is stacked on the n− type semiconductor layer 13. The Schottky electrode 14 may be formed by any known method. Examples of the method of forming the Schottky electrode 14 include a dry method and a wet method. Examples of the dry method include sputtering, vacuum deposition, and CVD. Examples of the wet method include screen printing and die coating. In a case where a material containing a metastable-phase crystalline oxide semiconductor (e.g., α-Ga₂O₃) is used as the n− type semiconductor layer 13, in step S7, regardless of which method is used to form the Schottky electrode 14, the n− type semiconductor layer 13 is in a state of less than 800° C. The temperature of the n− type semiconductor layer 13 is less than 800° C. from step S6 of forming the second region 13b to step S7 of forming the Schottky electrode 14. The temperature is preferably less than 600° C. in a case where α-Ga₂O₃ is used as the n− type semiconductor layer 13. In this embodiment, the Schottky electrode 14 is formed without performing a process of activating the ion-implanted impurity element.

According to this manufacturing method, it is possible to manufacture a semiconductor device 10 having improved breakdown voltage without using a p-type semiconductor region and having reduced electric field concentration at the outer peripheral edge of the Schottky electrode 14. Further, according to this manufacturing method, it is possible to manufacture a semiconductor device 10 provided with a first region 13a that contains a crystalline oxide semiconductor having a corundum structure as a major component.

### Second Embodiment

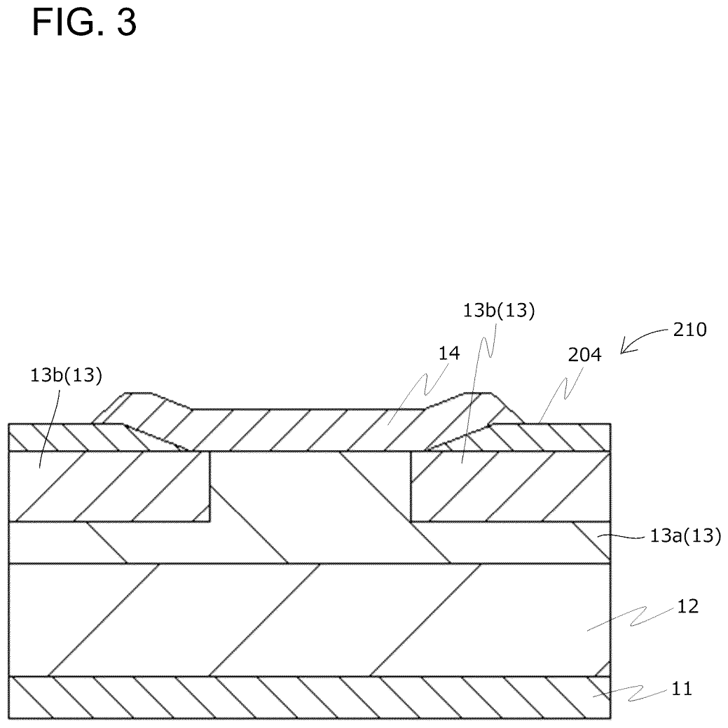

FIG. 3 is a schematic cross-sectional view illustrating a semiconductor device 210 according to a second embodiment. The semiconductor device 210 is a Schottky barrier diode (SBD) including an insulator layer 204. The semiconductor device 210 differs from the SBD of FIG. 1 in that an edge portion of the Schottky electrode 14 is located on the insulator layer 204. This configuration enables the semiconductor device to have better breakdown voltage characteristics. The constituent material of the insulator layer 204 may be any known material. Examples of the constituent material of the insulator layer 204 include an SiO₂ film, a phosphorus-doped SiO₂ film (PSG film), a boron-doped SiO₂ film, and a phosphorus-boron-doped SiO₂ film (BPSG film). The insulator layer 204 may be formed by any known method. Examples of the method of forming the insulator layer 204 include a vacuum deposition method, a CVD method, a sputtering method, and various coating techniques followed by patterning by a photolithography method or directly patterning by a printing technique.

### Third Embodiment

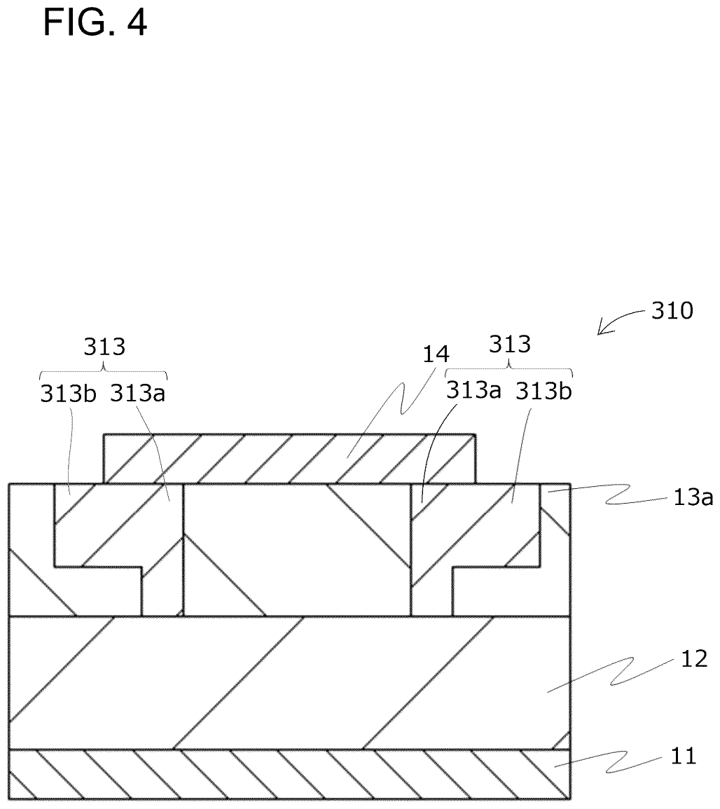

FIG. 4 is a schematic cross-sectional view illustrating a semiconductor device 310 according to a third embodiment. The semiconductor device 310 is a Schottky barrier diode (SBD) including a second region 313 formed in a shape different from that of the second region 13b shown in FIG. 1. The second region 313 includes a region 313a located inside the n− type semiconductor layer 13 in the horizontal direction, and a region 313b located outside the n− type semiconductor layer 13 in the horizontal direction from the region 313a. The region 313a is formed from the upper surface of n− type semiconductor layer 13 to a deeper position than the region 313b in the n− type semiconductor layer 13. The region 313b is formed, for example, at a peripheral portion of the n− type semiconductor layer 13 that does not include an outer peripheral edge of the n− type semiconductor layer 13. The region 313b overlaps, for example, the outer peripheral edge of the Schottky electrode 14 in a top view. The region 313a and the region 313b are formed by ion implantation, as in the second region 13b.

### Fourth Embodiment

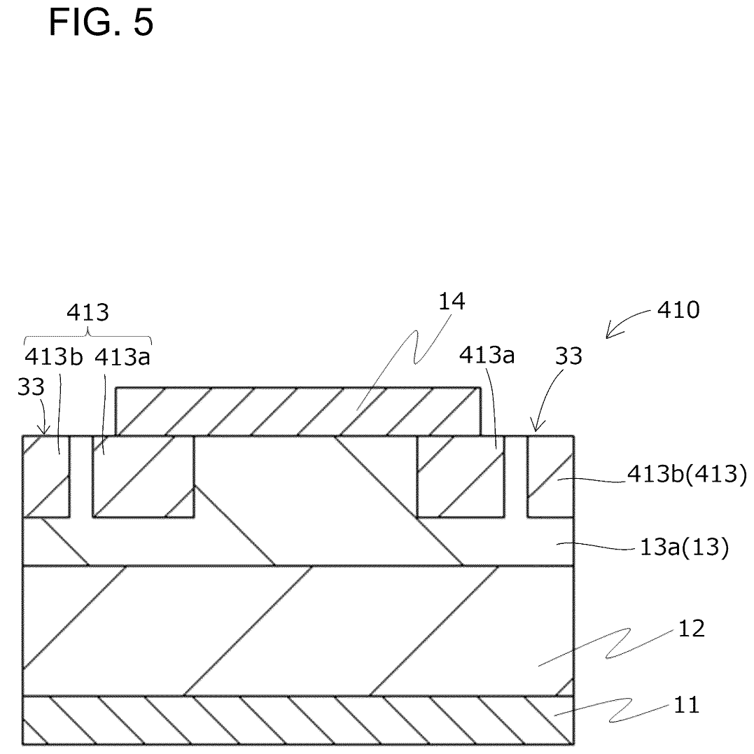

FIG. 5 is a schematic cross-sectional view illustrating a semiconductor device 410 according to a fourth embodiment. The semiconductor device 410 is a Schottky barrier diode (SBD) including a second region 413 in a place of the second region 13b shown in FIG. 1. The second region 413 includes a region 413a provided at a position overlapping a peripheral edge of the Schottky electrode 14 in a top view, and a region 413b provided at a position overlapping an outer peripheral edge of the n− type semiconductor layer 13 in a top view. The region 413a and the region 413b are not continuous and are provided separate from each other. The region 413a and the region 413b may each be formed by ion implantation in the same manner as the second region 13b. This configuration may also improve breakdown voltage without providing a p-type semiconductor region. Further, this configuration reduces the electric field concentration at the outer peripheral edge of the Schottky electrode 14.

### Fifth Embodiment

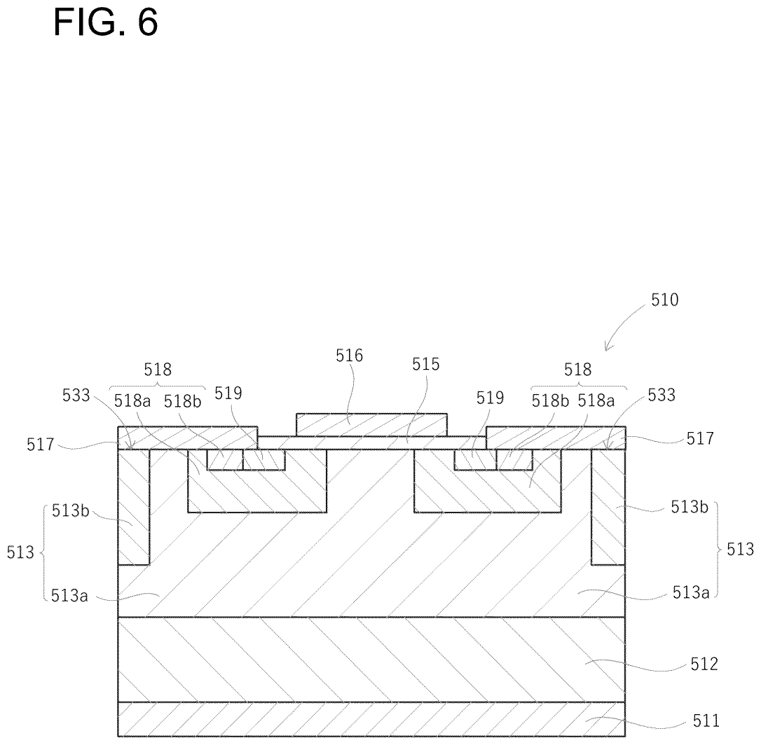

FIG. 6 is a schematic cross-sectional view illustrating a semiconductor device 510 according to a fifth embodiment. The semiconductor device 510 is a primary part of a metal oxide semiconductor field effect transistor (MOSFET) and includes a second region 513b in place of the second region 13b shown in FIG. 1. The semiconductor device 510 includes a drain electrode 511, an n+ type semiconductor layer 512, an n− type semiconductor layer (drift layer) 513, a gate insulating film 515, a gate electrode 516, and a source electrode 517.

In the MOSFET of FIG. 6, the n+ type semiconductor layer 512 and the n− type semiconductor layer 513 are stacked in this order on the drain electrode 511.

The n− type semiconductor layer 513 includes a first region 513a, a second region 513b, and oxide semiconductor layers 518a and 518b as p-well layers located in an upper portion of the n− type semiconductor layer 513. The MOSFET of FIG. 6 further includes an n+ type oxide semiconductor layer 519 inside the p-type oxide semiconductor layer 518a.

The first region 513a is a region of the n− type semiconductor layer 513 excluding the second region 513b and the oxide semiconductor layers 518 and 519. An upper surface of the first region 513a is bonded to a lower surface of the source electrode 517. The first region 513a includes the crystalline oxide semiconductor described in the description of the first region 13a.

The second region 513b is located on a side surface of the n− type semiconductor layer 513. The second region 513b overlaps a peripheral portion 533 of the n− type semiconductor layer 513 in a top view. The peripheral portion 533 is a region within a certain range inward from the side surface of the n− type semiconductor layer 513 to an area inward of the side surface. The certain range is, for example, a range that does not overlap the oxide semiconductor layer 518 in a top view.

An upper surface of the second region 513b is at least partially in contact with a portion of a lower surface of the source electrode 517. A portion of the second region 513b overlaps, for example, a periphery of the lower surface of the source electrode 517 and a portion within a certain range from the periphery to an area inward of the periphery in a top view. The lower surface of the second region 513b is, for example, located above the lower surface of the n− type semiconductor layer 513 and is not in contact with and separated from the upper surface of the n+ type semiconductor layer 512. Note that, the second region 513b includes the oxide described in the description of the second region 13b.

The gate electrode 516 is disposed on the oxide semiconductor layer 518a via the gate insulating film 515. Note that, the source electrode 517 is disposed so as to make contact with the n+ oxide semiconductor layer 519 and the oxide semiconductor layer 518b.

In the MOSFET of FIG. 6, the oxide semiconductor layer 518a and the n− type semiconductor layer 513 form the main junction. The MOSFET of FIG. 6 is a diode-embedded MOSFET and has a parasitic PN junction consisting of the p-type oxide semiconductor layer 518a and the n− type semiconductor layer 513, and an embedded Schottky barrier diode (SBD) consisting of the source electrode 517 and the n− type semiconductor layer 513. When the MOSFET of FIG. 6 is ON, a gate voltage above a threshold voltage is applied and a channel is formed in the p-type oxide semiconductor layer 518a in a range where the gate electrode 516 is in contact with the gate insulating film 515, causing a current to flow from the drain electrode 511 to the source electrode 517. When the MOSFET is OFF, the voltage applied between the drain electrode and the source electrode is blocked by the PN junction between the p-type oxide semiconductor layer 518a and the n− type semiconductor layer 513. When a positive voltage is applied to the source electrode 517 with respect to the drain electrode 511, a current flows through the embedded SBD. When an excessive current flows, holes are injected from the p-type oxide semiconductor layer (p-well layer) 518a, allowing a large current to flow at a low on-voltage in bipolar mode. When a negative voltage is applied to the source electrode 517 with respect to the drain electrode 511, the voltage applied between the drain electrode and the source electrode is blocked by the parasitic PN junction and the embedded SBD. Note that, although the MOSFET of FIG. 6 is described as a case of planar gate type, the MOSFET may be a trench gate type in the embodiments of the disclosure.

In the MOSFET of FIG. 6, the lower surface of the p-type oxide semiconductor layer 518a is located closer to the n-type oxide semiconductor layers (the n− type semiconductor layer 513 and the n+ type semiconductor layer 512) in the stacking direction of the semiconductor device (up-down direction in the figures) than the lower surface of the p-type oxide semiconductor layer 518b. Using such a structure, even if, for example, the band gap of the p-type oxide semiconductor layer 518b is smaller than that of the p-type oxide semiconductor layer 518a allows excellent semiconductor characteristics can be achieved while better preventing avalanche breakdown when a reverse bias is applied to the PN junction between the p-type oxide semiconductor layer 518a and the n-type semiconductor layer 513.

The hole carrier density of the p-type oxide semiconductor layer 518b is preferably greater than the hole carrier density of the p-type oxide semiconductor layer 518a. Setting the hole carrier density in such a desirable range, when an excessive current flows through the embedded Schottky barrier diode, allows a large current to flow at a low ON-voltage in bipolar mode due to hole injection from the p-type oxide semiconductor layer 518b. Further, it is also allowed ohmic contact resistance with the source electrode 517 to be reduced, and thus the avalanche current at turn-off to escape from the device to prevent device breakdown.

Note that multiple embodiments of the present disclosure described above can be combined, or some components can be applied to other embodiments. All such modifications belong to the embodiments of the disclosure.

In order to exhibit the functions described above, the semiconductor device of the disclosure described above can be applied to a power converter such as an inverter or a converter.

More specifically, it can be applied as a diode incorporated in the inverter or converter, a thyristor, a power transistor, an IGBT (Insulated Gate Bipolar Transistor), a MOSFET (Metal-Oxide-Semiconductor Field Effect Transistor or the like as a switching element.

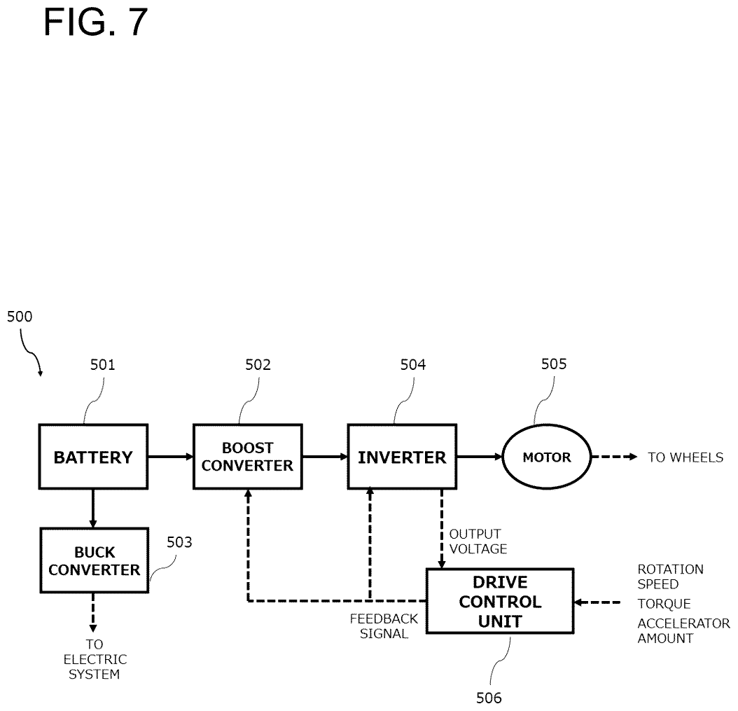

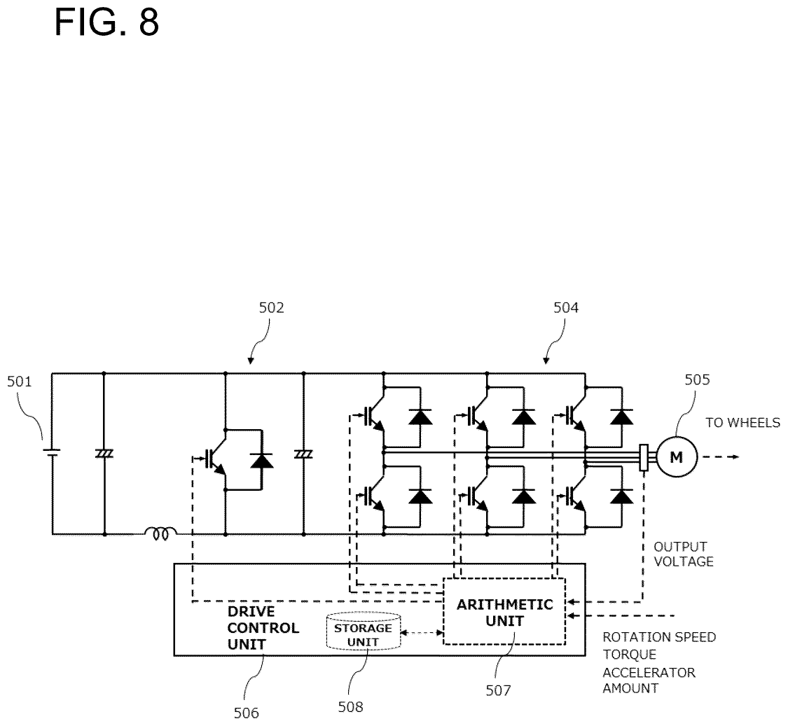

FIG. 7 is a block diagram illustrating an exemplary control system applying a semiconductor device according to an embodiment of the disclosure, and FIG. 8 is a circuit diagram of the control system particularly suitable for applying to a control system of an electric vehicle.

As shown in FIG. 7, the control system 500 includes a battery (power supply) 501, a boost converter 502, a buck converter 503, an inverter 504, a motor (driving object) 505, a drive control unit 506, which are mounted on an electric vehicle.

The battery 501 consists of, for example, a storage battery such as a nickel hydrogen battery or a lithium-ion battery. The battery 501 can store electric power by charging at the power supply station or regenerating at the time of deceleration, and to output a direct current (DC) voltage required for the operation of the driving system and the electrical system of the electric vehicle.

The boost converter 502 is, for example, a voltage converter in which a chopper circuit is mounted, and can step-up DC voltage of, for example, 200V supplied from the battery 501 to, for example, 650V by switching operations of the chopper circuit. The step-up voltage can be supplied to a traveling system such as a motor.

The buck converter 503 is also a voltage converter in which a chopper circuit is mounted, and can step-down DC voltage of, for example, 200V supplied from the battery 501 to, for example, about 12V. The step-down voltage can be supplied to an electric system including a power window, a power steering, or an electric device mounted on a vehicle.

The inverter 504 converts the DC voltage supplied from the boost converter 502 into three-phase alternating current (AC) voltage by switching operations, and outputs to the motor 505.

The motor 505 is a three-phase AC motor constituting the traveling system of an electric vehicle, and is driven by an AC voltage of the three-phase output from the inverter 504. The rotational driving force is transmitted to the wheels of the electric vehicle via a transmission mechanism (not shown).

On the other hand, actual values such as rotation speed and torque of the wheels, the amount of depression of the accelerator pedal (accelerator amount) are measured from an electric vehicle in cruising by using various sensors (not shown), The signals thus measured are input to the drive control unit 506.

The output voltage value of the inverter 504 is also input to the drive control unit 506 at the same time.

The drive control unit 506 has a function of a controller including an arithmetic unit such as a CPU (Central Processing Unit) and a data storage unit such as a memory, and generates a control signal using the inputted measurement signal and outputs the control signal as a feedback signal to the inverters 504, thereby controlling the switching operation by the switching elements.

The AC voltage supplied to the motor 505 from the inverter 504 is thus corrected instantaneously, and the driving control of the electric vehicle can be executed accurately. Safety and comfortable operation of the electric vehicle is thereby realized.

In addition, it is also possible to control the output voltage to the inverter 504 by providing a feedback signal from the drive control unit 506 to the boost converter 502.

FIG. 8 is a circuit configuration excluding the buck converter 503 in FIG. 7, in other words, a circuit configuration showing a configuration only for driving the motor 505.

As shown in the FIG. 8, the semiconductor device of the disclosure is provided for switching control by, for example, being applied to the boost controller 502 and the inverter 504 as a Schottky barrier diode.

The boost converter 502 performs chopper control by incorporating the semiconductor device into the chopper circuit of the boost converter 502. Similarly, the inverter 504 performs switching control by incorporating the semiconductor device into the switching circuit including an IGBT of the inverter 504.

The current can be stabilized by interposing an inductor (such as a coil) at the output of the battery 501. Also, the voltage can be stabilized by interposing a capacitor (such as an electrolytic capacitor) between each of the battery 501, the boost converter 502, and the inverter 504.

As indicated by a dotted line in FIG. 8, an arithmetic unit 507 including a CPU (Central Processing Unit) and a storage unit 508 including a nonvolatile memory are provided in the drive control unit 506.

Signal input to the drive control unit 506 is given to the arithmetic unit 507, and a feedback signal for each semiconductor element is generated by performing the programmed operation as necessary.

The storage unit 508 temporarily holds the calculation result by the calculation unit 507, stores physical constants and functions necessary for driving control in the form of a table, and outputs the physical constants, functions, and the like to the arithmetic unit 507 as appropriate.

The arithmetic unit 507 and the storage unit 508 can be provided by a known configuration, and the processing capability and the like thereof can be arbitrarily selected.

As shown in FIGS. 7 and 8, a diode and a switching element such as a thyristor, a power transistor, an IGBT, a MOSFET and the like is employed for the switching operation of the boost converter 502, the buck converter 503 and the inverter 504 in the control system 500.

The use of gallium oxide (Ga₂O₃) specifically corundum-type gallium oxide (α-Ga₂O₃) as its materials for these semiconductor devices greatly improves switching properties.

Further, extremely outstanding switching performance can be expected and miniaturization and cost reduction of the control system 500 can be realized by applying a semiconductor film or a semiconductor device of the disclosure.

That is, each of the boost converter 502, the buck converter 503 and the inverter 504 can be expected to have the benefit of the disclosure, and the effect and the advantages can be expected in any one or combination of the boost converter 502, the buck converter 503 and the inverter 504, or in any one of the boost converter 502, the buck converter 503 and the inverter 504 together with the drive control unit 506.

The control system 500 described above is not only applicable to the control system of an electric vehicle of the semiconductor device of the disclosure, but can be applied to a control system for any applications such as to step-up and step-down the power from a DC power source, or convert the power from a DC to an AC.

It is also possible to use a power source such as a solar cell as a battery.

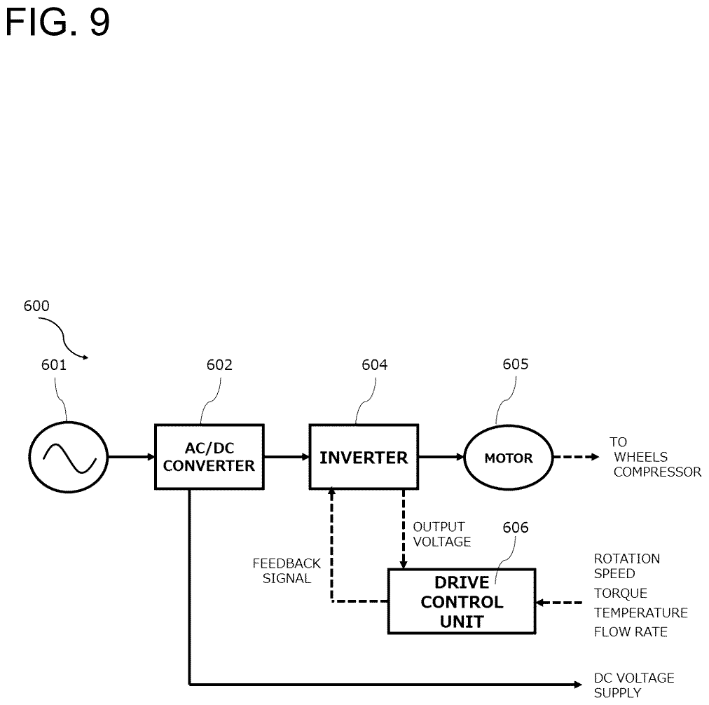

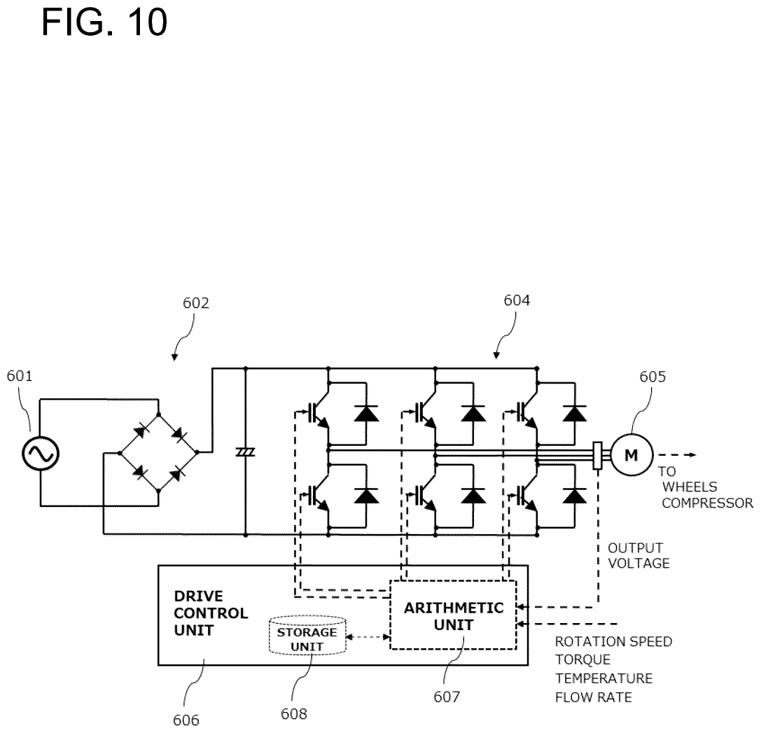

FIG. 9 is a block diagram illustrating another exemplary control system applying a semiconductor device according to an embodiment of the disclosure, and FIG. 10 is a circuit diagram of the control system suitable for applying to infrastructure equipment and home appliances or the like operable by the power from the AC power source.

As shown in FIG. 9, the control system 600 is provided for inputting power supplied from an external, such as a three-phase AC power source (power supply) 601, and includes an AC/DC converter 602, an inverter 604, a motor (driving object) 605 and a drive control unit 606 that can be applied to various devices described later.

The three-phase AC power supply 601 is, for example, a power plant (such as a thermal, hydraulic, geothermal, or nuclear plant) of an electric power company, whose output is supplied as an AC voltage while being downgraded through substations.

Further, the three-phase AC power supply 601 is installed in a building or a neighboring facility in the form of a private power generator or the like for supplying the generated power via a power cable.

The AC/DC converter 602 is a voltage converter for converting AC voltage to DC voltage. The AC/DC converter 602 converts AC voltage of 100V or 200V supplied from the three-phase AC power supply 601 to a predetermined DC voltage.

Specifically, AC voltage is converted by a transformer to a desired, commonly used voltage such as 3. 3V, 5V, or 12V.

When the driving object is a motor, conversion to 12V is performed.

It is possible to adopt a single-phase AC power supply in place of the three-phase AC power supply. In this case, same system configuration can be realized if an AC/DC converter of the single-phase input is employed.

The inverter 604 converts the DC voltage supplied from the AC/DC converter 602 into three-phase AC voltage by switching operations and outputs to the motor 605.

Configuration of the motor 605 is variable depending on the control object. It can be a wheel if the control object is a train, can be a pump and various power source if the control objects a factory equipment, can be a three-phase AC motor for driving a compressor or the like if the control object is a home appliance. The motor 605 is driven to rotate by the three-phase AC voltage output from the inverter 604, and transmits the rotational driving force to the driving object (not shown).

There are many kinds of driving objects such as personal computer, LED lighting equipment, video equipment, audio equipment and the like capable of directly supplying a DC voltage output from the AC/DC converter 602. In that case the inverter 604 becomes unnecessary in the control system 600, and a DC voltage from the AC/DC converter 602 is supplied to the driving object directly as shown in FIG. 9.

Here, DC voltage of 3. 3V is supplied to personal computers and DC voltage of 5V is supplied to the LED lighting device for example.

On the other hand, rotation speed and torque of the driving object, measured values such as the temperature and flow rate of the peripheral environment of the driving object, for example, is measured using various sensors (not shown), these measured signals are input to the drive control unit 606.

At the same time, the output voltage value of the inverter 604 is also input to the drive control unit 606. Based on these measured signals, the drive control unit 606 provides a feedback signal to the inverter 604 thereby controls switching operations by the switching element of the inverter 604.

The AC voltage supplied to the motor 605 from the inverter 604 is thus corrected instantaneously, and the operation control of the driving object can be executed accurately. Stable operation of the driving object is thereby realized.

In addition, when the driving object can be driven by a DC voltage, as described above, feedback control of the AC/DC converter 602 is possible in place of feedback control of the inverter 604.

FIG. 10 shows the circuit configuration of FIG. 9.

As shown in FIG. 10, the semiconductor device of the disclosure is provided for switching control by, for example, being applied to the AC/DC converter 602 and the inverter 604 as a Schottky barrier diode.

The AC/DC converter 602 has, for example, a circuit configuration in which Schottky barrier diodes are arranged in a bridge-shaped, to perform a direct-current conversion by converting and rectifying the negative component of the input voltage to a positive voltage.

Schottky barrier diodes can also be applied to a switching circuit in IGBT of the inverter 604 to perform switching control.

The voltage can be stabilized by interposing a capacitor (such as an electrolytic capacitor) between the AC/DC converter 602 and the inverter 604.

As indicated by a dotted line in FIG. 10, an arithmetic unit 607 including a CPU and a storage unit 608 including a nonvolatile memory are provided in the drive control unit 606.

Signal input to the drive control unit 606 is given to the arithmetic unit 607, and a feedback signal for each semiconductor element is generated by performing the programmed operation as necessary.

The storage unit 608 temporarily holds the calculation result by the arithmetic unit 607, stores physical constants and functions necessary for driving control in the form of a table, and outputs the physical constants, functions, and the like to the arithmetic unit 607 as appropriate.

The arithmetic unit 607 and the storage unit 608 can be provided by a known configuration, and the processing capability and the like thereof can be arbitrarily selected.

In such a control system 600, similarly to the control system 500 shown in FIGS. 7 and 8, a diode or a switching element such as a thyristor, a power transistor, an IGBT, a MOSFET or the like is also applied for the purpose of the rectification operation and switching operation of the AC/DC converter 602 and the inverter 604.

Switching performance can be improved by the use of gallium oxide (Ga₂O₃), particularly corundum-type gallium oxide (α-Ga₂O₃), as materials for these semiconductor elements.

Further, extremely outstanding switching performance can be expected and miniaturization and cost reduction of the control system 600 can be realized by applying a semiconductor film or a semiconductor device of the disclosure.

That is, each of the AC/DC converter 602 and the inverter 604 can be expected to have the benefit of the disclosure, and the effects and the advantages of the disclosure can be expected in any one or combination of the AC/DC converter 602 and the inverter 604, or in any of the AC/DC converter 602 and the inverter 604 together with the drive control unit 606.

Although the motor 605 has been exemplified in FIGS. 9 and 10, the driving object is not necessarily limited to those that operate mechanically. Many devices that require an AC voltage can be a driving object.

It is possible to apply the control system 600 as long as electric power is obtained from AC power source to drive the driving object. The control system 600 can be applied to the driving control of any electric equipment such as infrastructure equipment (electric power facilities such as buildings and factories, telecommunication facilities, traffic control facilities, water and sewage treatment facilities, system equipment, labor-saving equipment, trains and the like) and home appliances (refrigerators, washing machines, personal computers, LED lighting equipment, video equipment, audio equipment and the like).

### Other Modifications

When each crystalline oxide semiconductor and/or each oxide is a mixed crystal, the band gap of the crystalline oxide semiconductor or oxide can be controlled by using indium and aluminum individually or in combination to form a mixed crystal. In this case, such mixed crystal constitutes an extremely attractive family of material as an InAlGaO-based semiconductor. Here, InAlGaO-based semiconductors indicate In_{X}Al_{Y}Ga_{Z}O₃ (0≤X≤2, 0≤Y≤2, 0≤Z≤2, X+Y+Z=1.5 to 2.5) and nay be regarded as a family of materials including gallium oxide.

In the embodiments described above, the impurity is defined as an element different from the element constituting the major component of the second region 13b, 313, 413, 513b. However, when the dopant concentration in the first region 13a and the second region 13b, 313, 413, 513b are similar, the impurity may be defined as an element having a higher concentration in the second region 13b, 313, 413, 513b than in the first region 13a. For example, the crystalline oxide semiconductor contained as a major component in the first region 13a and the oxide contained as a major component in the second region 13b, 313, 413, 513b may be a mixture of gallium and aluminum, and the impurity may be aluminum. In this case, the concentration of aluminum is higher in the second region 13b, 313, 413, 513b than in the first region 13a.

The second region 13b, 313, 413, 513b may overlap only with a portion of the peripheral edge of the Schottky electrode 14 in a top view. Further, the second region 13b may not overlap with the outer peripheral edge of the n− type semiconductor layer 13 in a top view and instead overlap with a portion further inward. The second region 13b may overlap the outer peripheral edge of the n− type semiconductor layer 13 in a top view and may not overlap the outer peripheral edge of the Schottky electrode 14 in a top view. Similarly, one of the regions 413a and 413b may not be provided.

The second regions 13b, 313, 413, 513b may be entirely located within the n− type semiconductor layer 13, 513 and may not be partially exposed from the n− type semiconductor layers 13, 513, respectively. The thickness of the second region 13b, 313, 413, 513b may be 1.0 μm or greater, for example, 1.5 μm or greater.

As long as the semiconductor device of the present disclosure is manufacturable, the order of each step may differ from the order in the embodiment described above. In the embodiment described above, the ohmic electrode 11 is formed prior to the Schottky electrode 14, but the Schottky electrode 14 may be formed prior to the ohmic electrode 11. In this case, in the step of forming the ohmic electrode 11, the temperature of the n− type semiconductor layer 13 is set to less than 800° C. Additionally, the position of the substrate and other components to be removed in the manufacturing process may differ between the semiconductor layers 12 and 13. For example, the semiconductor device of the disclosure may be manufactured as follows: the n+ type semiconductor layer 12 is stacked on the substrate 15, the n− type semiconductor layer 13 is stacked on the n+ type semiconductor layer 12, the substrate 15 is removed from the n+ type semiconductor layer 12 (a modification of step S5), the ohmic electrode 11 is stacked on the n+ type semiconductor layer 12 (step S3), the support substrate is bonded to the ohmic electrode 11 (step S4), the second region 13b is formed in the n− type semiconductor layer 13 (step S6), and the Schottky electrode 14 is stacked on the n− type semiconductor layer 13 (step S7). The semiconductor device according to the disclosure may also be manufactured as follows: the n+ type semiconductor layer 12 is stacked on the substrate 15, the n− type semiconductor layer 13 is stacked on n+ type semiconductor layer 12, the second region 13b is formed on the n− type semiconductor layer 13 (step S6), the substrate 15 is removed from the n+ type semiconductor layer 12 (a modification of step S5), the ohmic electrode 11 is stacked on the n+ type semiconductor layer 12 (step S3), the support substrate is bonded to the ohmic electrode 11 (step S4), and the Schottky electrode 14 is stacked on the n− type semiconductor layer 13 (step S7).

Further, in the embodiments of the disclosure, the semiconductor film may be directly deposited on the base or substrate, or may be deposited via another layer such as a stress relaxation layer (e.g., a buffer layer or an ELO layer) or an exfoliation sacrifice layer. The method of forming each layer is not limited and may be any known method, but a mist CVD method is preferred in the embodiments of the disclosure. In the embodiments of the disclosure, the semiconductor film may be used in a semiconductor device as the semiconductor layer after using a known method such as exfoliating to separate the semiconductor film from the base, or may be used as is in a semiconductor device as the semiconductor layer.

An additional semiconductor layer may be provided between the n− type semiconductor layer 13 and the Schottky electrode 14. In this case, the additional semiconductor layer is stacked after the second region 13b is provided in the n− type semiconductor layer 13.

In the embodiments of the disclosure, an annealing process may be performed after the deposition step. The treatment temperature for annealing is, for example, from 300° C. to 650° C., preferably from 350° C. to 550° C. The treatment time for annealing is, for example, from 1 minute to 48 hours, preferably from 10 minutes to 24 hours, more preferably from 30 minutes to 12 hours. Note that, the annealing process may be performed under any atmosphere. The atmosphere may be a non-oxygen atmosphere or an oxygen atmosphere. Examples of the non-oxygen atmosphere include an inert gas atmosphere (e.g., nitrogen atmosphere) and a reducing gas atmosphere. In the embodiments of the disclosure, an inert gas atmosphere is preferred, and a nitrogen atmosphere is more preferred.

### EXAMPLES

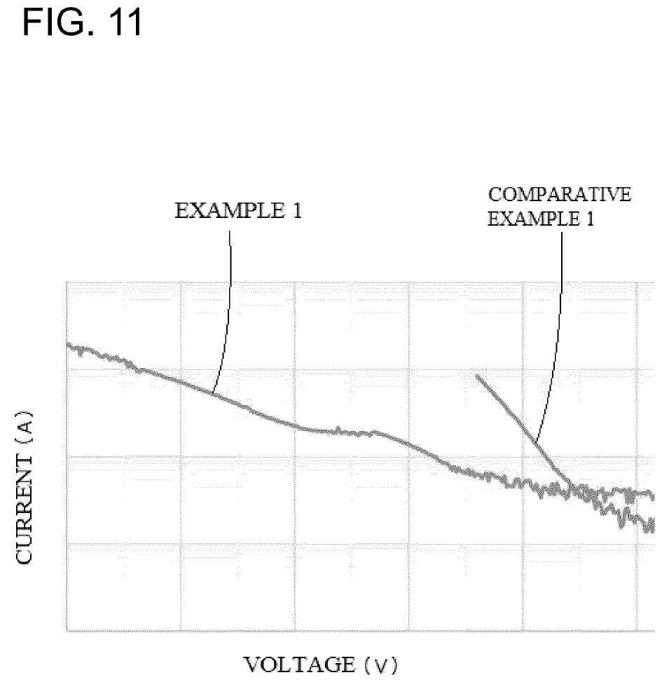

The semiconductor devices of the present disclosure are described below as Example 1 and Comparative Example 1 with reference to FIG. 1 and FIG. 11. FIG. 11 is a view showing the relationship between voltage (V) and current (A) when a reverse voltage is applied to the semiconductor devices in Example 1 and Comparative Example 1. In FIG. 11, the horizontal axis represents the magnitude of the value of the voltage (V) when the reverse voltage is applied, with the absolute value of the voltage (V) increasing from the right to the left. In FIG. 11, the vertical axis represents the magnitude of the value of the current (A), with the current value increasing from the lower side to the upper side.

A semiconductor device shown in FIG. 1 was produced by the method of manufacturing according to the first embodiment, and this was used as Example 1. In Example 1, an Al element was ion implanted as an impurity into the n− type semiconductor layer 13 at an implantation energy of 2000 keV and a dose of 3.0×10¹³ atoms/cm². In Example 1, a device with a maximum implantation energy of 8 MeV was used. A semiconductor device was produced using the same method of manufacturing as that in the first embodiment except that the second region 13b was not provided, and this was used as Comparative Example 1.

The reverse voltage was evaluated for each of the obtained semiconductor devices. The evaluation was performed by applying a reverse voltage from 0 to 1200 V to each of the obtained semiconductor devices and measuring the voltage when a current of 0.2 μA or more flowed and when the reverse voltage was stopped and a current of 0.1 μA flowed. The device used was a B1505A power device analyzer manufactured by Keysight Technologies.

As shown in FIG. 11, an increase in the current value is suppressed in Example 1 as compared to Comparative Example 1, even when the value (absolute value) of the reverse voltage is increased. From this, it is understood that the breakdown voltage of the semiconductor device is enhanced by providing the second region 13b. Note that, the absolute value of the reverse voltage when the current value exceeds 1.0×10⁻⁷ A was about twice as high in Example 1 as in Comparative Example 1.

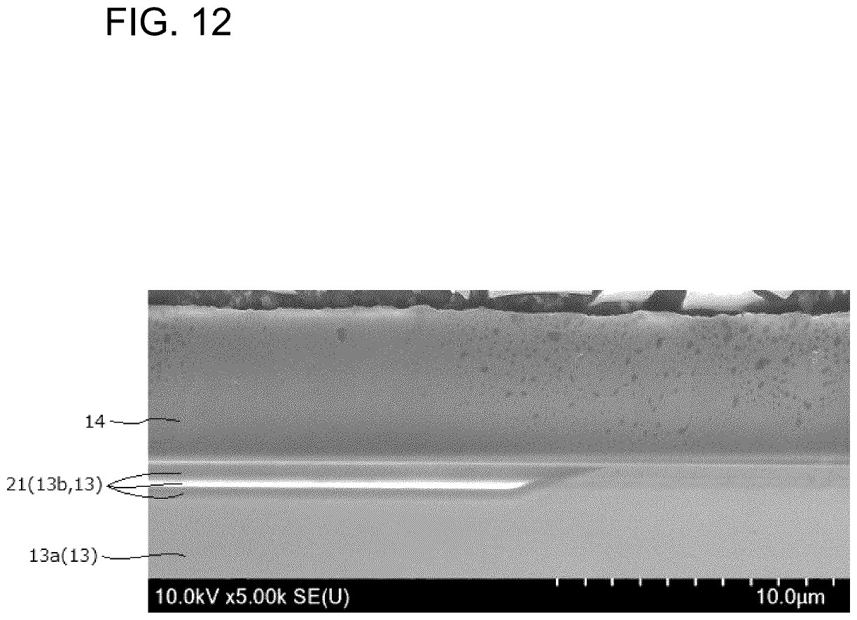

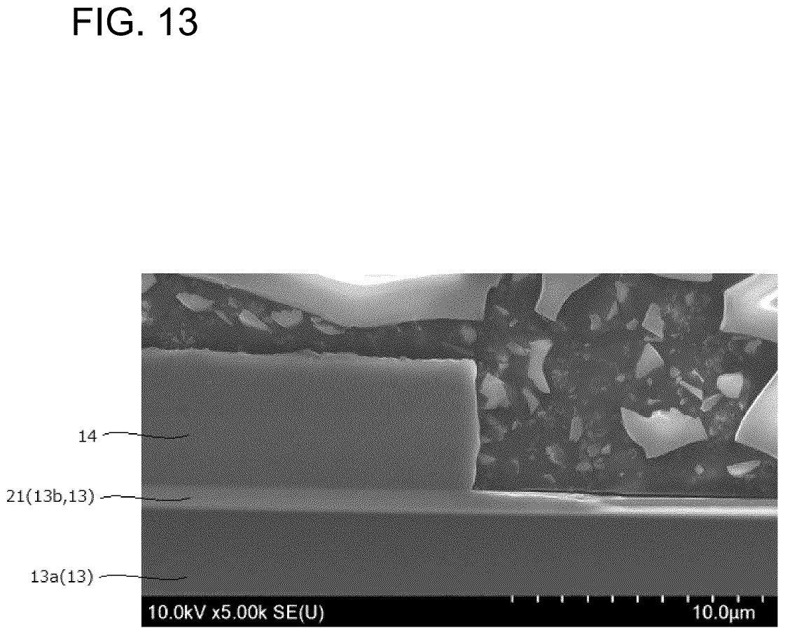

When the obtained semiconductor device was observed using SEM, the results shown in FIGS. 12 and 13 were obtained. FIGS. 12 and 13 each show a cross-section perpendicular to the upper surface of the semiconductor layer of the obtained semiconductor device. FIG. 12 is an image of an area inside the peripheral edge of the Schottky electrode 14. FIG. 13 is an image including the peripheral edge of the Schottky electrode 14. A linear region with high resistance was observed in the n− type semiconductor layer 13. This region extended along the upper surface.

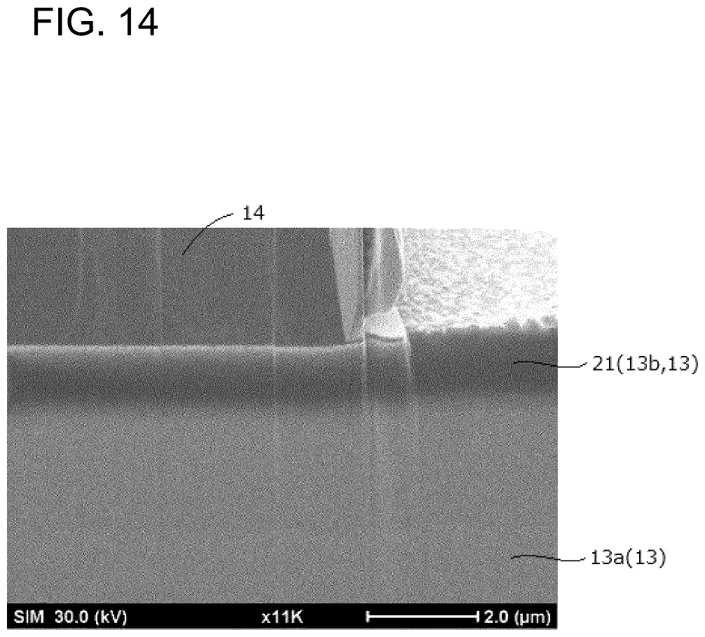

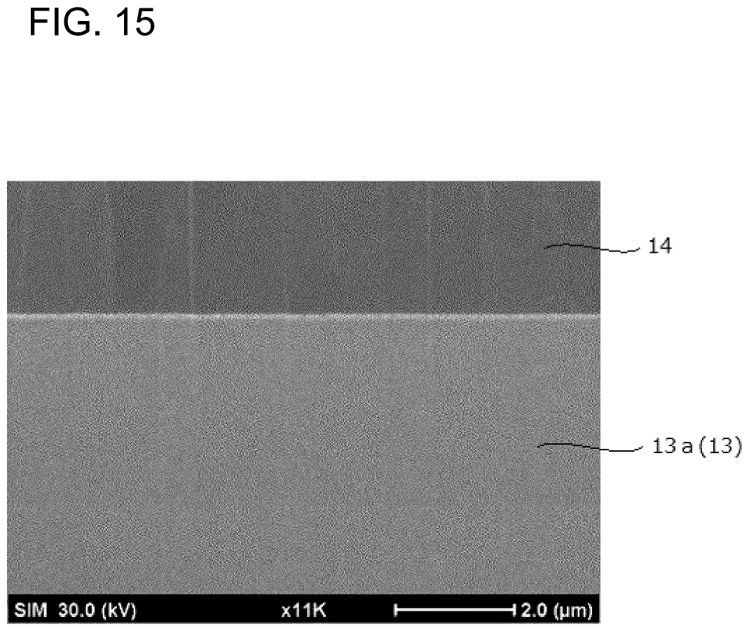

When the obtained semiconductor device was observed using SIM, the results shown in FIGS. 14 and 15 were obtained. FIGS. 14 and 15 each show a cross-section perpendicular to the upper surface of the semiconductor layer of the obtained semiconductor device. FIG. 14 is an image including a peripheral edge of the Schottky electrode 14. A linear region with high resistance was observed in the n− type semiconductor layer 13. This region extended along the upper surface. FIG. 15 is an image of the center of the Schottky electrode 14 in the horizontal direction. For the results shown in FIG. 15, observation was performed on a part that did not include the second region 13b. In FIG. 15, the linear region with high resistance was not observed.

Note that in both the SEM and SIM observations, the region having high resistance was observed to be thinner than the thickness of the second region 13b, which was measured by secondary ion mass spectrometry (SIMS). In other words, in the SEM and SIM observations, it was not necessary to observe a part of the second region 13b, more specifically, it was not necessary to observe the lower edge of the second region 13b.

The relationship between the depth from the upper surface of the semiconductor layer and the density of crystal defects or the concentration of the impurity element was as shown in FIG. 16, which shows results of calculation using numerical calculation codes (SRIM/TRIM). FIG. 17 shows the density of gallium (Ga) crystal defects, the density of oxygen (O) crystal defects, and the density of gallium and oxygen (Ga+O) crystal defects at depths from the upper surface of the semiconductor layer. FIG. 16 also shows the depth and density of aluminum (Al) element (the impurity element in Example 1) from the upper surface of the semiconductor layer. The range of the second region 13b in depth from the upper surface of the semiconductor layer can be identified because the depth of the impurity element can be determined from the results of calculation by numerical codes (SRIM/TRIM).

The maximum value of the density of each crystal defect was located at a depth position from the upper surface of the semiconductor layer closer to the lower edge of the second region than the upper edge of the second region. The maximum value of the density of each crystal defect was shallower from the upper surface of the semiconductor layer than the maximum value of the concentration of the impurity element in the second region, and both of these maximum values were located at a depth position from the upper surface of the semiconductor layer closer to the lower edge of the second region than the upper edge of the second region. The aluminum (Al) element had a maximum concentration at the depth 1.3 to 1.4 μm and the same concentration as the dopant concentration in the n− type semiconductor layer 13 at the depth 1.6 to 1.7 μm. Thus, the boundary between the second region 13b and the first region 13a can also be calculated by numerical codes. In other words, the boundary between the second region 13b and the first region 13a may be defined as the above-described depth at which the concentration of the impurity element in the second region 13b becomes the same as the dopant concentration of the n− type semiconductor layer 13 at a deeper position than the maximum value. Note that, the TRIM program is available from http://www.srim.org as part of a group of programs known as SRIM.

Semiconductor devices of the disclosure are described below using Examples 2 to 7 with reference to FIG. 17. FIG. Note that 17 shows the result of secondary ion mass spectrometry (SIMS) showing the relationship between the depth from the upper surface of the n− type semiconductor layer 13 and the concentration of impurities in Examples 2 to 5. The horizontal axis in FIG. 17 represents the depth from the upper surface of the n− type semiconductor layer 13, and the unit is m. The vertical axis of FIG. 17 represents the concentration (N) of the impurity element (Al element), and the unit is cm⁻³.

Semiconductor devices were produced by the same method as the method of manufacturing according to the first embodiment except that elements were ion implanted across the entire upper surface of the n− type semiconductor layer 13. The impurity elements and ion implantation conditions in Examples 2 to 5 and Comparative Examples 2 to 3 are as follows.

### Example 2

In Example 2, Al element was ion implanted into the n− type semiconductor layer 13 at an implantation energy of 1500 keV and a dose of 3.0×10¹³ atoms/cm². In Example 2, a device with a maximum implantation energy of 8 MeV was used. Secondary ion mass spectrometry (SIMS) analysis of the obtained semiconductor device showed that the maximum value of the concentration of the Al element was located at a depth of 1.0 μm or slightly deeper than 1.0 μm from the upper surface of the n− type semiconductor layer 13, as shown in FIG. 17.

### Example 3

In Example 3, Al element was ion implanted into the n− type semiconductor layer 13 at an implantation energy of 2000 keV and a dose of 3.0×10¹³ atoms/cm². In Example 3, a device with a maximum implantation energy of 8 MeV was used. Secondary ion mass spectrometry (SIMS) analysis of the obtained semiconductor device showed that the maximum value of the concentration of the Al element was located at a depth of about 1.25 μm from the upper surface of the n− type semiconductor layer 13, as shown in FIG. 17.

### Example 4

In Example 4, Al element was ion implanted into the n− type semiconductor layer 13 at an implantation energy of 3000 keV and a dose of 3.0×10¹³ atoms/cm². In Example 4, a device with a maximum implantation energy of 8 MeV was used. Secondary ion mass spectrometry (SIMS) analysis of the obtained semiconductor device showed that the maximum value of the concentration of the Al element was located at a depth of about 1.55 μm from the upper surface of the n− type semiconductor layer 13, as shown in FIG. 17.

### Example 5

In Example 5, Al element was ion implanted into the n− type semiconductor layer 13 at an implantation energy of 2000 keV and a dose of 1.0×10¹³ atoms/cm². In Example 5, a device with a maximum implantation energy of 8 MeV was used. Secondary ion mass spectrometry (SIMS) analysis of the obtained semiconductor device showed that the maximum value of the concentration of the Al element was located at a similar depth from the upper surface of the n− type semiconductor layer 13 as Example 3.

### Example 6

In Example 6, Mg element was ion implanted into the n− type semiconductor layer 13 with a double charge at an implantation energy of 600 keV and a dose of 4.0×10¹⁴ atoms/cm². In Example 6, a device with a maximum implantation energy of 400 keV was used.

### Example 7

In Example 7, B element was ion implanted into the n− type semiconductor layer 13 with a double charge at an implantation energy of 600 keV and a dose of 4.0×10¹⁴ atoms/cm². In Example 7, a device with a maximum implantation energy of 400 keV was used.

The reverse voltage was evaluated for each of the obtained semiconductor devices. The evaluation was performed by applying a reverse voltage from 0 to 1200 V to each of the obtained semiconductor devices and measuring the voltage when a current of 0.2 μA or more flowed and when the reverse voltage was stopped and a current of 0.1 μA flowed. The device used was a B1505A power device analyzer manufactured by Keysight Technologies.

The absolute value of the reverse voltage in each Example when the current value exceeded 1.0×10⁻⁸ A was greater than 800 V in Example 2, greater than 950 V in Example 4, and greater than 1000 V in Examples 3 and 4. In addition, the absolute values were 650 V to 700 V in Example 6 and 550 V to 600 V in Example 7. From these values, it can be understood that the breakdown voltage of the semiconductor device is increased in the Examples. It can also be understood that the impurity Al with a mass number greater than that of Mg is more preferable.

The relationship between the range Rp+ΔRp (m) obtained by adding a projected range Rp, which indicates the depth of ion implantation into the n− type semiconductor layer 13, and a standard deviation ΔRp, and the dielectric breakdown voltage (V) was evaluated for Examples 2 to 7. In Examples 2 to 5, the dielectric breakdown voltage exceeded 800 V in every Example and favorable resistance was obtained from the relationship. In Examples 6 and 7, Rp+ΔRp was 1.0 μm or less, which meant that the dielectric breakdown voltage was poor as compared to the Examples in which Al element was implanted.

The above-described embodiments are appended below.

### [Structure 1]

A semiconductor device including: a semiconductor layer with an extended depletion layer; and an electrode disposed on the semiconductor layer directly or via another layer, the semiconductor layer including a first region containing, as a major component, a crystalline oxide semiconductor containing gallium, and a second region containing, as a major component, an oxide containing gallium, the second region including a linear crystal defect region in a cross section perpendicular to an upper surface of the semiconductor layer.

### [Structure 2]

The semiconductor device according to [Structure 1], wherein a density of crystal defects in the crystal defect region is 1.0×10¹⁹/cm³ or more.

### [Structure 3]

The semiconductor device according to [Structure 1] or [Structure 2], wherein a surface density of crystal defects in the second region in a top view is 5×10¹⁶/cm² or more.

### [Structure 4]

The semiconductor device according to any one of [Structure 1] to [Structure 3], wherein the crystal defect region extends along the upper surface of the semiconductor layer.

### [Structure 5]

The semiconductor device according to any one of [Structure 1] to [Structure 4], wherein a maximum value of the density of the crystal defects in the crystal defect region is located at a position at a depth from the upper surface, closer to a lower edge of the second region than an upper edge of the second region.

### [Structure 6]

The semiconductor device according to any one of [Structure 1] to [Structure 5], wherein the semiconductor layer includes an impurity element, a concentration of the impurity element in the second region is higher than a concentration of the impurity element in the first region, the maximum value of the density of the crystal defects in the crystal defect region is shallower in depth from the upper surface of the semiconductor layer than a maximum concentration of the impurity element in the second region, and both of the maximum values are located at a position at a depth from the upper surface, closer to the lower edge of the second region than the upper edge of the second region.

### [Structure 7]

The semiconductor device according to any one of [Structure 1] to [Structure 6], wherein a thickness of the second region is 1.5 m or more.

### [Structure 8]

The semiconductor device according to any one of [Structure 1] to [Structure 7], wherein at least a portion of the second region overlaps a peripheral edge of a lower surface of the electrode in a top view.

### [Structure 9]

The semiconductor device according to [Structure 7], wherein the portion of the second region overlapping the peripheral edge of the lower surface is in contact with the lower surface.

### [Structure 10]

The semiconductor device according to any one of [Structure 1] to [Structure 9], wherein at least a portion of the second region overlaps a peripheral portion of the semiconductor layer.

### [Structure 11]

The semiconductor device according to any one of [Structure 1] to [Structure 10], wherein the second region contains a simple element having a mass number greater than that of Mg.

### [Structure 12]

The semiconductor device according to [Structure 10], wherein the element is Al.

### [Structure 13]

The semiconductor device according to any one of [Structure 1] to [Structure 12], wherein, in the second region, a concentration of an element is greater than in the first region.

### [Structure 14]

The semiconductor device according to any one of [Structure 1] to [Structure 13], wherein the crystalline oxide semiconductor has a corundum structure.

### [Structure 15]

The semiconductor device according to any one of [Structure 1] to [Structure 14], wherein the oxide is amorphous.

### [Structure 16]

The semiconductor device according to any one of [Structure 1] to [Structure 15], wherein the crystalline oxide semiconductor includes aluminum and/or indium.

### [Structure 17]

The semiconductor device according to any one of [Structure 1] to [Structure 16], the semiconductor device being a diode.

### [Structure 18]

The semiconductor device according to any one of [Structure 1] to [Structure 17], the semiconductor device being a power device.

### [Structure 19]

A power conversion device using the semiconductor device described in any one of [Structure 1] to [Structure 18].

### [Structure 20]

A control system using the semiconductor device described in any one of [Structure 1] to [Structure 18].

### [Structure 21]

A method of manufacturing a semiconductor device, the method including: forming a semiconductor layer containing, as a major component, a crystalline oxide semiconductor containing gallium, and an n-type dopant; ion implanting an impurity element into a portion of the semiconductor layer from an upper surface of the semiconductor layer; and forming an electrode on the semiconductor layer directly or via another layer without performing processing of activating the ion-implanted element, ion implanting including forming a first region containing, as a major component, a crystalline oxide semiconductor containing gallium, and a second region containing, as a major component, an oxide containing gallium, and forming a linear crystal defect region in the second region in a cross section perpendicular to the upper surface of the semiconductor layer.

### [Structure 22]

The method of manufacturing a semiconductor device according to [Structure 21], wherein, after ion implanting, a temperature of the semiconductor layer is less than 800° C. until the step of forming the electrode.

The embodiments of the present invention are exemplified in all respects, and the scope of the present invention includes all modifications within the meaning and scope equivalent to the scope of claims.

### REFERENCE SIGNS LIST

10, 210, 310, 410, 510 Semiconductor device
11 Ohmic electrode
12, 512 n+ type semiconductor layer
13, 513 n− type semiconductor layer
13a, 513a First region
13b, 313, 413, 513b Second region
14 Schottky electrode
15 Substrate
21 Crystal defect region
33 Peripheral portion
204 Insulator layer
313a, 313b, 413a, 413b Region
511 Drain electrode
515 Gate insulating film
516 Gate electrode
517 Source electrode
518, 518a, 518b Oxide semiconductor layer
519 n+ type oxide semiconductor layer
533 Peripheral portion

What is claimed is:

1. A semiconductor device comprising:
a semiconductor layer with an extended depletion layer; and
an electrode disposed on the semiconductor layer directly or via another layer,
the semiconductor layer including a first region containing, as a major component, a crystalline oxide semiconductor containing gallium, and a second region containing, as a major component, an oxide containing gallium,
the second region including a linear crystal defect region in a cross section perpendicular to an upper surface of the semiconductor layer.

2. The semiconductor device according to claim 1, wherein a density of crystal defects in the crystal defect region is 1.0×10¹⁹/cm³ or more.

3. The semiconductor device according to claim 1, wherein a surface density of crystal defects in the second region in a top view is 5×10¹⁶/cm² or more.

4. The semiconductor device according to claim 1, wherein the crystal defect region extends along the upper surface of the semiconductor layer.

5. The semiconductor device according to claim 1, wherein a maximum value of the density of the crystal defects in the crystal defect region is located at a position at a depth from the upper surface, closer to a lower edge of the second region than an upper edge of the second region.

6. The semiconductor device according to claim 1, wherein
the semiconductor layer includes an impurity element,
a concentration of the impurity element in the second region is higher than a concentration of the impurity element in the first region,
the maximum value of the density of the crystal defects in the crystal defect region is shallower in depth from the upper surface of the semiconductor layer than a maximum concentration of the impurity element in the second region, and
both of the maximum values are located at a position at a depth from the upper surface, closer to the lower edge of the second region than the upper edge of the second region.

7. The semiconductor device according to claim 1, wherein a thickness of the second region is 1.5 μm or more.

8. The semiconductor device according to claim 1, wherein at least a portion of the second region overlaps a peripheral edge of a lower surface of the electrode in a top view.

9. The semiconductor device according to claim 1, wherein the second region contains a simple element having a mass number greater than that of Mg.

10. The semiconductor device according to claim 9, wherein the element is Al.

11. The semiconductor device according to claim 1, wherein, in the second region, a concentration of an element is greater than in the first region.

12. The semiconductor device according to claim 1, wherein the crystalline oxide semiconductor has a corundum structure.

13. The semiconductor device according to claim 1, wherein the oxide is amorphous.

14. The semiconductor device according to claim 1, wherein the crystalline oxide semiconductor includes aluminum and/or indium.

15. The semiconductor device according to claim 1, the semiconductor device being a diode.

16. The semiconductor device according to claim 1, the semiconductor device being a power device.

17. A power conversion device using the semiconductor device described in claim 1.

18. A control system using the semiconductor device described in claim 1.

19. A method of manufacturing a semiconductor device, the method comprising:
forming a semiconductor layer containing, as a major component, a crystalline oxide semiconductor containing gallium, and an n-type dopant;
ion implanting an impurity element into a portion of the semiconductor layer from an upper surface of the semiconductor layer; and
forming an electrode on the semiconductor layer directly or via another layer without performing processing of activating the ion-implanted element,
ion implanting including forming a first region containing, as a major component, a crystalline oxide semiconductor containing gallium, and a second region containing, as a major component, an oxide containing gallium, and forming a linear crystal defect region in the second region in a cross section perpendicular to the upper surface of the semiconductor layer.

20. The method of manufacturing a semiconductor device according to claim 19, wherein, after ion implanting, a temperature of the semiconductor layer is less than 800° C. until the step of forming the electrode.
